(19) United States
(12) Patent Application Publication
(10) Pub. No.: US 2023/0124169 A1
(43) Pub. Date: Apr. 20, 2023

(54) SOLID-STATE IMAGING DEVICE AND ELECTRONIC DEVICE

(71) Applicant: SONY SEMICONDUCTOR SOLUTIONS CORPORATION, KANAGAWA (JP)

(72) Inventors: TOSHIAKI IWAFUCHI, KANAGAWA (JP); KEISUKE AOKI, KANAGAWA (JP)

(21) Appl. No.: 17/904,949

(22) PCT Filed: Feb. 16, 2021
(86) PCT No.: PCT/JP2021/005754

§ 371 Date: Aug. 24, 2022

(30) Foreign Application Priority Data
Mar. 5, 2020 (JP) 2020-037544

(51) Int. Cl. H04N 25/70

(52) U.S. Cl. CPC H04N 25/70

(57) ABSTRACT

A solid-state imaging device capable of suppressing the occurrence of flare is provided. The solid-state imaging device includes a substrate on which a plurality of photoelectric conversion units are formed, a groove that is formed between a pixel region having the plurality of photoelectric conversion units and a blade region surrounding the pixel region such that the groove is opened near the light-receiving surface of the substrate and surrounds the pixel region, and a light absorber that is disposed in the groove and absorbs light.

### TECHNICAL FIELD

The present technique relates to a solid-state imaging device and an electronic device.

### BACKGROUND ART

A conventionally proposed solid-state imaging device has a groove that is formed between a blade region and a pixel region and surrounds the pixel area (for example, see PTL 1). In the solid-state imaging device described in PTL 1, the groove blocks film stripping or cracks that may occur when a wafer is divided.

### CITATION LIST

### Patent Literature

[PTL 1]
JP 2011-114261 A

### SUMMARY

### Technical Problem

In the solid-state imaging device described in PTL 1, however, incident light on the solid-state imaging device is reflected by the inner wall surface or the bottom surface of the groove, the reflected incident light is reflected by an IR filter disposed near the light-receiving surface of the solid-state imaging device, and unnecessary light comes into the pixel region, which may cause flare.

An object of the present disclosure is to provide a solid-state imaging device and an electronic device that can suppress the occurrence of flare.

### Solution to Problem

A solid-state imaging device according to the present disclosure includes (a) a substrate on which a plurality of photoelectric conversion units are formed, (b) a substrate on which a plurality of photoelectric conversion units are formed, (b) a groove that is formed between a pixel region having the plurality of photoelectric conversion units and a blade region surrounding the pixel region such that the groove is opened near the light-receiving surface of the substrate and surrounds the pixel region, and (c) a light absorber that is disposed in the groove and absorbs light.

A solid-state imaging device according to the present disclosure includes (a) a substrate on which a plurality of photoelectric conversion units are formed, (b) a substrate on which a plurality of photoelectric conversion units are formed, (b) a groove that is formed between a pixel region having the plurality of photoelectric conversion units and a blade region surrounding the pixel region such that the groove is opened near the light-receiving surface of the substrate and surrounds the pixel region, and (c) a low-refractivity material that is disposed in the groove and has a lower refractivity than a material forming the substrate.

A solid-state imaging device according to the present disclosure includes (a) a substrate on which a plurality of photoelectric conversion units are formed, (b) a wiring layer stacked on the opposite side from the light-receiving surface of the substrate, and (c) a groove that is formed between a pixel region having the plurality of photoelectric conversion units and a blade region surrounding the pixel region such that the groove is opened near the light-receiving surface of the substrate and surrounds the pixel region, wherein (d) the groove is so deep as to penetrate the substrate.

A solid-state imaging device according to the present disclosure includes (a) a substrate on which a plurality of photoelectric conversion units are formed and (b) a groove that is formed between a pixel region having the plurality of photoelectric conversion units and a blade region surrounding the pixel region such that the groove is opened near the light-receiving surface of the substrate and surrounds the pixel region, wherein (c) the groove has an uneven pattern on the bottom surface of the groove.

A solid-state imaging device according to the present disclosure includes (a) a substrate on which a plurality of photoelectric conversion units are formed and (b) a plurality of grooves that are formed between a pixel region having the plurality of photoelectric conversion units and a blade region surrounding the pixel region such that the grooves are opened near the light-receiving surface of the substrate and surround the pixel region, wherein (c) each of the grooves has an opening covered with a light-reflective material that reflects light, and (d) the light-reflective material covering each of the grooves has a flat surface.

An electronic device according to the present disclosure includes (a) a solid-state imaging device including a substrate on which a plurality of photoelectric conversion units are formed, a groove that is formed between a pixel region having the plurality of photoelectric conversion units and a blade region surrounding the pixel region such that the groove is opened near the light-receiving surface of the substrate and surrounds the pixel region, and a light absorber that is disposed in the groove and absorbs light, (b) an optical lens that forms image light from a subject into an image on the imaging surface of the solid-state imaging device, and (c) a signal processing circuit that performs signal processing on a signal output from the solid-state imaging device.

An electronic device according to the present disclosure includes (a) a substrate on which a plurality of photoelectric conversion units are formed, (b) a groove that is formed between a pixel region having the plurality of photoelectric conversion units and a blade region surrounding the pixel region such that the groove is opened near the light-receiving surface of the substrate and surrounds the pixel region, and (c) a low-refractivity material that is disposed in the groove and has a lower refractivity than a material forming the substrate.

An electronic device according to the present disclosure includes (a) a solid-state imaging device including a substrate on which a plurality of photoelectric conversion units are formed, a wiring layer stacked on the opposite side from the light-receiving surface of the substrate, and a groove that is formed between a pixel region having the plurality of photoelectric conversion units and a blade region surrounding the pixel region such that the groove is opened near the light-receiving surface of the substrate and surrounds the pixel region, the groove being so deep as to penetrate the substrate, (b) an optical lens that forms image light from a subject into an image on the imaging surface of the solid-state imaging device, and (c) a signal processing circuit that performs signal processing on a signal output from the solid-state imaging device.

### BRIEF DESCRIPTION OF DRAWINGS

FIG. 1 is a diagram illustrating the overall configuration of a solid-state imaging device according to a first embodiment.

FIG. 2A is a diagram illustrating the planar configuration of a chip where the solid-state imaging device is formed.

FIG. 2B is a diagram illustrating the planar configurations of the chips where the solid-state imaging device is formed.

FIG. 3 is a diagram illustrating a cross-sectional configuration of the chip along line A-A of FIG. 2A.

FIG. 4A is a diagram illustrating a cross-sectional configuration of a camera module.

FIG. 4B is a diagram illustrating a cross-sectional configuration of a camera module as an enlarged view of an area B of FIG. 4A.

FIG. 5 is a diagram illustrating a cross-sectional configuration of a chip according to a modification.

FIG. 6 is a diagram illustrating a cross-sectional configuration of a chip according to a modification.

FIG. 7A is a diagram illustrating a step of forming a groove.

FIG. 7B is a diagram illustrating a step of forming the groove.

FIG. 7C is a diagram illustrating a step of forming the groove.

FIG. 7D is a diagram illustrating a step of forming the groove.

FIG. 7E is a diagram illustrating a step of forming the groove.

FIG. 7F is a diagram illustrating a step of forming the groove.

FIG. 7G is a diagram illustrating a step of forming the groove.

FIG. 7H is a diagram illustrating a step of forming the groove.

FIG. 7I is a diagram illustrating a step of forming the groove.

FIG. 8 is a diagram illustrating a cross-sectional configuration of a chip according to a modification.

FIG. 9A is a diagram illustrating a step of forming the groove.

FIG. 9B is a diagram illustrating a step of forming the groove.

FIG. 9C is a diagram illustrating a step of forming the groove.

FIG. 9D is a diagram illustrating a step of forming the groove.

FIG. 9E is a diagram illustrating a step of forming the groove.

FIG. 9F is a diagram illustrating a step of forming the groove.

FIG. 10 is a diagram illustrating a cross-sectional configuration of a chip according to a second embodiment.

FIG. 11 is a diagram illustrating a cross-sectional configuration of the chip according to a modification.

FIG. 12 is a diagram illustrating a cross-sectional configuration of the chip according to a modification.

FIG. 13 is a diagram illustrating a cross-sectional configuration of the chip according to a modification.

FIG. 14 is a diagram illustrating the planar configuration of a chip where a solid-state imaging device is formed according to a third embodiment.

FIG. 15 is a diagram illustrating a cross-sectional configuration of the chip along line B-B of FIG. 14.

FIG. 16A is a diagram illustrating a step of forming a groove.

FIG. 16B is a diagram illustrating a step of forming the groove.

FIG. 16C is a diagram illustrating a step of forming the groove.

FIG. 16D is a diagram illustrating a step of forming the groove.

FIG. 16E is a diagram illustrating a step of forming the groove.

FIG. 16F is a diagram illustrating a step of forming the groove.

FIG. 16G is a diagram illustrating a step of forming the groove.

FIG. 16H is a diagram illustrating a step of forming the groove.

FIG. 17 is a diagram illustrating a cross-sectional configuration of the chip according to a modification.

FIG. 18 is a diagram illustrating a cross-sectional configuration of a chip according to a fourth embodiment.

FIG. 19 is a schematic diagram of an electronic device according to a fifth embodiment.

### DESCRIPTION OF EMBODIMENTS

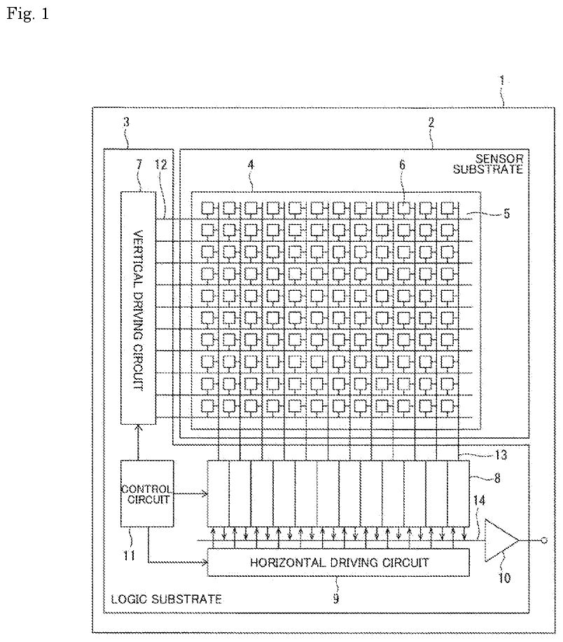

Hereinafter, examples of a solid-state imaging device and an electronic device according to embodiments of the present disclosure will be described with reference to FIGS. 1 to 19. The embodiments of the present disclosure will be described in the following order. Note, however, that the present disclosure is not limited to the following examples. In addition, the effects described in this specification are exemplary and not limiting, and other effects may be provided.

### 1. First Embodiment: Solid-State Imaging Device

### 1-1 Overall Configuration of Solid-State Imaging Device

### 1-2 Configuration of Main Part

### 1-3 Modifications

### 2. Second Embodiment: Solid-State Imaging Device

### 2-1 Configuration of Main Part

### 2-2 Modifications

### 3. Third Embodiment: Solid-State Imaging Device

### 3-1 Configuration of Main Part

### 3-2 Method of Manufacturing Chip

### 3-3 Modifications

### 4. Fourth Embodiment: Solid-State Imaging Device

### 4-1 Configuration of Main Part

### 5. Fifth Embodiment: Electronic Device

### 1. First Embodiment

### [1-1 Overall Configuration of Solid-State Imaging Device]

A solid-state imaging device according to the first embodiment of the present disclosure will be described below. FIG. 1 is a schematic configuration diagram illustrating the entire solid-state imaging device according to the first embodiment of the present disclosure.

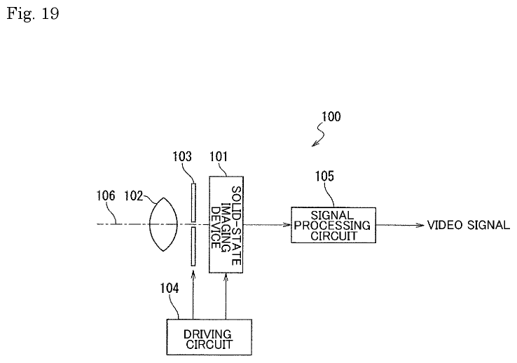

A solid-state imaging device 1 in FIG. 1 is a backside irradiation type complementary metal oxide semiconductor (CMOS) image sensor. As illustrated in FIG. 19, the solid-state imaging device 1 (101) takes in image light (incident light 106) from a subject through an optical lens 102, converts the amount of incident light 106 imaged on an imaging surface into an electrical signal in units of pixels, and outputs the electrical signal as a pixel signal.

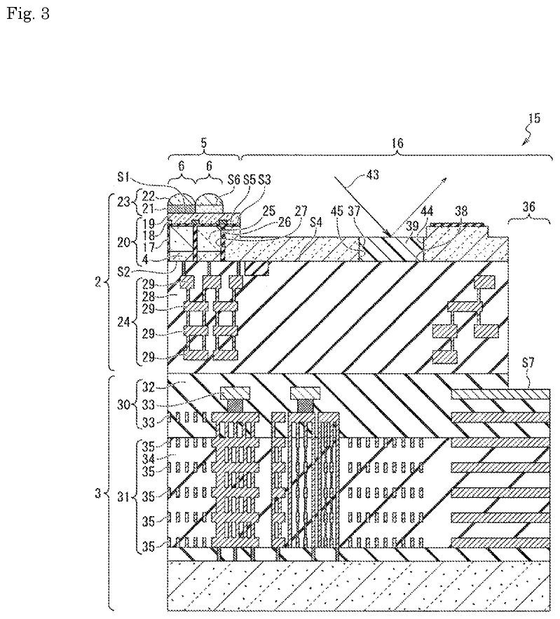

As illustrated in FIGS. 1 and 3, the solid-state imaging device 1 includes a sensor substrate 2 and a logic substrate 3 stacked on the sensor substrate 2. In FIG. 1, the sensor substrate 2 and the logic substrate 3 are illustrated on the same plane for the convenience of explanation.

As illustrated in FIG. 1, the sensor substrate 2 includes a substrate 4 and a pixel region 5.

The pixel region 5 includes a plurality of pixels 6 arranged regularly in a two-dimensional array on the substrate 4. The pixel 6 includes a photoelectric conversion unit 25 illustrated in FIG. 3, and a plurality of pixel transistors (not illustrated). As the plurality of pixel transistors, for example, four transistors, that is, a transfer transistor, a reset transistor, a selection transistor, and an amplifier transistor can be adopted. In addition, for example, the three transistors other than the selection transistor may be employed.

The logic substrate 3 includes a vertical driving circuit 7, column signal processing circuits 8, a horizontal driving circuit 9, an output circuit 10, and a control circuit 11.

The vertical driving circuit 7 including, for example, a shift register selects a desired pixel driving wiring 12, supplies a pulse for driving the pixels 6 to the selected pixel driving wiring 12, and drives the pixels 6 in units of rows. Specifically, the vertical driving circuit 7 sequentially performs selection scanning on the pixels 6 in the pixel region 5 in a vertical direction in units of rows, and supplies a pixel signal based on a signal charge generated in accordance with the amount of light received in the photoelectric conversion unit 25 of each of the pixels 6, to the column signal processing circuits 8 through vertical signal lines 13.

The column signal processing circuit 8 is disposed, for example, for each column of the pixels 6, and performs, for each pixel column, signal processing such as noise removal on signals output from the pixels 6 corresponding to one row. For example, the column signal processing circuit 8 performs signal processing such as correlated double sampling (CDS) and analog digital (AD) conversion for removing pixel-specific fixed pattern noise.

The horizontal driving circuit 9 including, for example, a shift register sequentially outputs horizontal scanning pulses to the column signal processing circuits 8, selects the column signal processing circuits 8 in a sequential order, and outputs a pixel signal having been subjected to signal processing to a horizontal signal line 14 from each of the column signal processing circuits 8.

The output circuit 10 performs signal processing on the pixel signals sequentially supplied from the column signal processing circuits 8 through the horizontal signal line 14 and outputs the signals. Examples of the signal processing which may be used include buffering, black level adjustment, column variation correction, and various types of digital signal processing.

The control circuit 11 generates a clock signal or a control signal as a reference for operations of the vertical driving circuit 7, the column signal processing circuit 8, the horizontal driving circuit 9, and the like on the basis of a vertical synchronization signal, a horizontal synchronization signal, and a master clock signal. In addition, the control circuit 11 outputs the generated clock signal or control signal to the vertical driving circuit 7, the column signal processing circuit 8, the horizontal driving circuit 9, and the like.

In the first embodiment, the sensor substrate 2 only includes the substrate 4 and the pixel region 5. In addition, the sensor substrate 2 may include some of the constituent elements of the logic substrate 3, for example, the vertical driving circuit 7 and the horizontal driving circuit 9.

### [1-2 Configuration of Main Part]

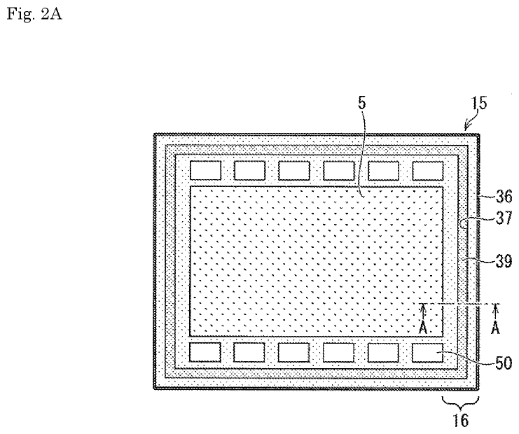

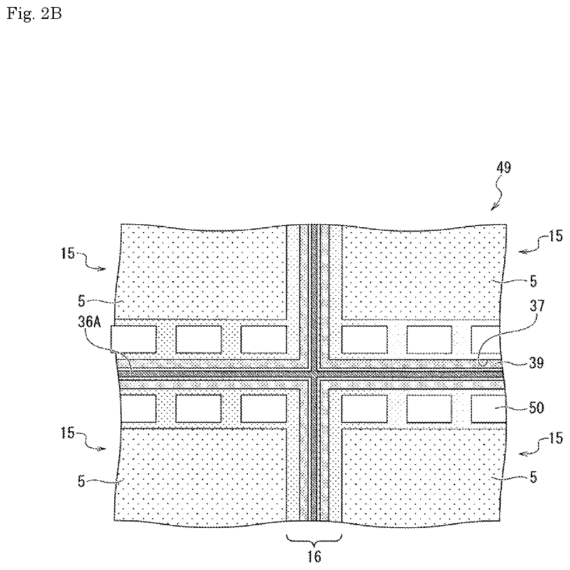

A detailed structure of a chip 15 where the solid-state imaging device 1 in FIG. 1 is formed will be described below. FIG. 2A is a diagram illustrating a planar configuration of the pixel region 5 and a peripheral region thereof (hereinafter also referred to as “scribe region 16”) in the chip 15 where the solid-state imaging device 1 is formed. FIG. 2B is a diagram illustrating a planar configuration of the scribe region 16 in a wafer 49 where the chips 15 are formed. FIG. 3 is a diagram illustrating a cross-sectional configuration of the chip 15 along line A-A of FIG. 2A.

As illustrated in FIG. 3, the chip 15 where the solid-state imaging device 1 (the sensor substrate 2, the logic substrate 3) includes a light receiving layer 20 in which the substrate 4, an insulating film 17, a light shielding film 18, and a flattened film 19 are stacked in this order. In addition, a light collecting layer 23 in which a color filter layer 21 and an on-chip lens 22 are stacked in this order is formed on a surface of the light receiving layer 20, near the flattened film 19 (hereinafter, also referred to as “near a back side S1”). Furthermore, a wiring layer 24 is stacked on a surface of the light receiving layer 20 near the substrate 4 (hereinafter, also referred to as “near a front side S2”). Meanwhile, the back side S1 of the light receiving layer 20 and the back side of the flattened film 19 are flush with each other, and thus the back side of the flattened film 19 will be also referred to as “back side S1” in the following description. In addition, the front side S2 of the light receiving layer 20 and the front side of the substrate 4 are flush with each other, and thus the front side of the substrate 4 will be also referred to as “front side S2” in the following description.

The substrate 4 includes a semiconductor substrate made of, for example, silicon (Si) and forms the pixel region 5 and the scribe region 16. In the pixel region 5, the pixels 6 are arranged in a two-dimensional array, the pixel 6 including the photoelectric conversion unit 25. Each of the photoelectric conversion units 25 embedded in the substrate 4 constitutes a photodiode, generates a signal charge according to the amount of incident light, and stores the generated signal charge. Moreover, on the substrate 4, a plurality of I/O pads 50 are disposed along at least one of the sides of the pixel region 5. FIG. 2A illustrates the I/O pads 50 disposed along two parallel sides of the pixel region 5 (the upper side and the lower side in FIG. 2A).

The photoelectric conversion units 25 are physically separated by a pixel separating portion 26. The pixel separating portion 26 is formed in a grid shape to surround the photoelectric conversion units 25. The pixel separating portion 26 has a trench portion 27 (groove) formed with a bottom from a surface of the substrate 4 near the insulating film 17 (hereinafter, will be also referred to as “back side S3”) in the depth direction. In other words, the trench portion 27 is formed between the adjacent photoelectric conversion units 25 near the back side S3 of the substrate 4. The trench portion 27 is formed in a grid shape like the pixel separating portion 26 such that the inner sides and the bottom form the outside shape of the pixel separating portion 26. FIG. 3 illustrates the trench portion 27 penetrating the substrate 4 and the wiring layer 24 having a surface S4 facing the substrate 4, the surface S4 forming the bottom of the trench portion 27. Moreover, in the trench portion 27, the insulating film 17 covering the back side S3 of the substrate 4 is embedded.

The insulating film 17 seamlessly covers the overall back side S3 (the overall light receiving surface) of the substrate 4 and the inside of the trench portion 27. The material of the insulating film 17 can be, for example, an insulating material. For example, silicon oxide (SiO₂) and silicon nitride (SiN) can be used. In addition, on a part of a back side S5 of the insulating film 17, the light shielding film 18 is formed in a grid shape that opens the light receiving surfaces of the photoelectric conversion units 25 without leaking light into the adjacent pixel 6. The flattened film 19 seamlessly covers the overall back side S5 (the overall light receiving surface) of the insulating film 17 as well as the light shielding film 18 such that the back side S1 of the light receiving layer 20 has a flat surface without asperities.

The color filter layer 21 has a plurality of color filters of R (red), G (green), and B (blue) and the like for each of the pixels 6 near the back side S1 (the light receiving surface) of the flattened film 19. The colors of the color filters are arranged according to, for example, a Bayer array. The color filter layer 21 transmits light having a specific wavelength and allows the transmitted light to enter the photoelectric conversion units 25 in the substrate 4.

The on-chip lens 22 corresponding to each of the pixels 6 is formed on a back side S6 (the light receiving surface) of the color filter layer 21. The on-chip lens 22 collects emitted light and allows the collected light to efficiently enter the photoelectric conversion unit 25 in the substrate 4 through the color filter layer 21.

The wiring layer 24 is formed on the front side S2 of the substrate 4 and includes an interlayer insulation film 28 and wirings 29. The wirings 29 are disposed in multiple layers, and the interlayer insulation film 28 is present between the wirings 29. This provides insulation between the wirings 29. The material of the interlayer insulation film 28 can be, for example, silicon oxide. A method of forming the interlayer insulation film 28 can be, for example, plasma chemical vapor deposition (CVD) using Tetraethoxysilane (TEOS) as source gas. The wiring 29 can be, for example, a copper (Cu) wiring.

The logic substrate 3 includes a first multilayer wiring layer 30 bonded to the sensor substrate 2 (wiring layer 24), and a second multilayer wiring layer 31 stacked on the opposite side from a surface (a surface near the light receiving surface) of the first multilayer wiring layer 30, the surface being bonded to the sensor substrate 2 (wiring layer 24).

The first multilayer wiring layer 30 includes an interlayer insulation film 32 and wirings 33. The wirings 33 are disposed in multiple layers, and the interlayer insulation film 32 is present between the wirings 33. This provides insulation between the wirings 33. The material of the interlayer insulation film 32 can be, for example, silicon oxide. A method of forming the interlayer insulation film 32 can be, for example, plasma CVD using TEOS as source gas. Using plasma CVD with TEOS serving as source gas can increase the density and strength of the interlayer insulation film 32, thereby preventing, for example, the entry of water. The wiring 33 can be, for example, a copper (Cu) wiring or an aluminum (Al) wiring.

The second multilayer wiring layer 31 includes an interlayer insulation film 34 and wirings 35. The wirings 35 are disposed in multiple layers, and the interlayer insulation film 34 is present between the wirings 35. This provides insulation between the wirings 35. The material of the interlayer insulation film 34 can be, for example, a material having a lower dielectric constant than the interlayer insulation film 32 of the first multilayer wiring layer 30. For example, low dielectric constant materials (low-k materials) including carbon-doped silicon oxide (SiOC) and nitrogen-doped silicon nitride (SiON) can be used. Using a low-k material as the material of the interlayer insulation film 34 can reduce a capacitance between the wirings. A method of forming the interlayer insulation film 34 can be, for example, plasma CVD or coating formation. The wiring 35 can be, for example, a copper wiring.

In the chip 15 where the sensor substrate 2 having the above-described configuration is formed, light is emitted from the back side of the substrate 4 (the back side S1 of the light receiving layer 20), the emitted light passes through the on-chip lenses 22 and the color filter layer 21, and the transmitted light is subjected to photoelectric conversion by the photoelectric conversion units 25, thereby generating signal charges. The generated signal charges are then output as pixel signals by vertical signal lines 13, which are illustrated in FIG. 1, through the pixel transistors formed near the front side S2 of the substrate 4.

On the outer side of the scribe region 16, a blade region 36 (hereinafter will be also referred to as “the blade region 36 after a division”) is formed around the pixel region 5 as illustrated in FIGS. 2A and 3. As illustrated in FIG. 2B, the blade region 36 after a division is a region formed by dicing (dividing) the bottom surface of a grooved blade region 36A (hereinafter will be also referred to as “the blade region 36A before a division”) that is formed from the back side S3 of the substrate 4 in the depth direction between the chips 15 formed on the wafer 49. The blade region 36A before a division has a larger width than a blade. This can prevent the blade from coming into contact with the substrate 4 during the dicing of the chips 15, thereby preventing the substrate 4 from peeling off or cracking. The blade region 36 after a division has a bottom surface S7 in the wiring layer 24. FIG. 3 illustrates the wiring 33 near the substrate 4 such that the wiring 33 forms the bottom surface S7 of the blade region 36 after a division.

As illustrated in FIGS. 2A and 3, on the inner side of the scribe region 16, that is, between the blade region 36 after a division and the pixel region 5, a groove 37 (slit) with a bottom is formed around the pixel region 5 and the I/O pads 50 and is opened near the back side S3 of the substrate 4 (near the light receiving surface). The groove 37 has a bottom surface 38 formed at the interface between the wiring layer 24 and the substrate 4 of the sensor substrate 2. In other words, the groove 37 penetrates the substrate 4, and the surface S4 of the wiring layer 24 (hereinafter will be also referred to as “back side S4”) forms the bottom surface 38 of the groove 37, the surface S4 facing the substrate 4.

As described above, the solid-state imaging device 1 according to the first embodiment has a structure in which the blade region 36 before a division is increased in width, so that the substrate 4 hardly peels off or cracks. Even in such a structure, a blade may come into contact with the substrate 4 and cause the substrate 4 to peel off. To address the problem, the groove 37 is provided between the blade region 36 after a division and the pixel region 5, thereby preventing peeling and the like from extending into the pixel region 5.

As illustrated in FIG. 3, a light absorber 39 that absorbs light is disposed in the groove 37. The light absorber 39 is embedded to reach an opening in the groove 37 and fills the groove 37. The light absorber 39 can be, for example, a resin containing a pigment. As the pigment, at least one of, for example, carbon black, titan black, and pigment black can be used. The resin can be, for example, a resin prepared by the reaction of a resin containing a carboxyl group with an unsaturated compound containing a glycidyl group, a resin prepared by the polymerization of a (meta)acrylic ester compound containing a hydroxyl group, or (meta)acrylic acid-2-ethyl isocyanate.

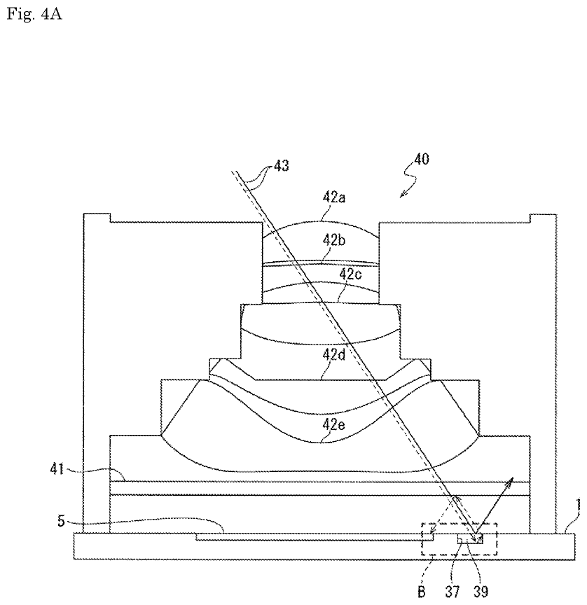

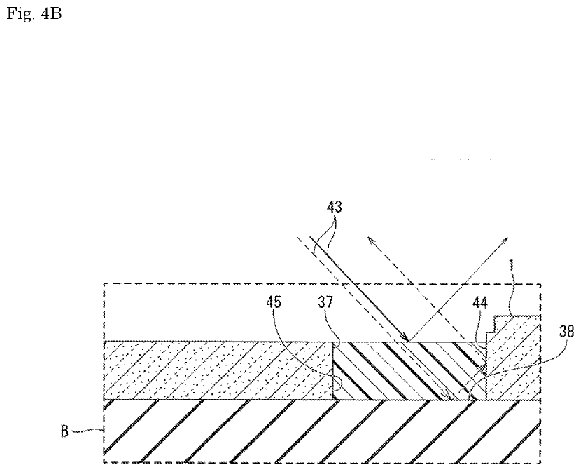

As described above, the solid-state imaging device 1 has a structure including the groove 37 that hardly extends peeling or cracks into the pixel region 5. However, such a structure may cause flare when a camera module 40 is configured as illustrated in FIG. 4A. Specifically, in the configuration of the camera module 40 including an IR cut filter 41 disposed on the solid-state imaging device 1 and imaging lenses 42a, 42b, 42c, 42d, and 42e disposed on the IR cut filter 41, when incident light 43 enters the groove 37 through the imaging lenses 42a to 42e and the IR cut filter 41, the incident light 43 is reflected by inner wall surfaces 44 and 45 and the bottom surface 38 of the groove 37 and travels toward the pixel region 5 as indicated by dotted lines in FIG. 4B, the incident light 43 is reflected by the IR cut filter 41 and the imaging lenses 42a to 42e and the like, and the reflected incident light 43 returns into the pixel region 5. This may cause flare. Such flare is likely to occur particularly if the pixel region 5 and the groove 37 are close to each other on some sides of the groove 37 while the I/O pads 50 are not present between the sides (the left side and the right side in FIG. 2A) and the pixel region 5.

To address the problem, the light absorber 39 is disposed in the groove 37 in the solid-state imaging device 1 according to the first embodiment. Thus, even if the incident light 43 enters the groove 37, the light absorber 39 absorbs the incident light 43 as indicated by a solid line in FIG. 4B. This can suppress the reflection of the incident light 43 by the inner wall surfaces 44 and 45 and the bottom surface 38 of the groove 37, prevent the reflected incident light 43 from returning to the pixel region 5, and prevent the reflected incident light 43 from entering the pixel region 5, thereby suppressing the occurrence of flare.

Moreover, the groove 37 is filled with the light absorber 39, so that the energy of cracks can be absorbed by the light absorber 39 and the effect of suppressing the extension of cracks into the pixel region 5 can be expected.

As described above, in the solid-state imaging device 1 according to the first embodiment, the light absorber 39 that absorbs light is disposed in the groove 37 between the blade region 36 and the pixel region 5. Thus, the solid-state imaging device 1 can be provided such that the incident light 43 can be absorbed by the light absorber 39, for example, when the incident light 43 enters the groove 37, and the reflection of the incident light 43 by the inner wall surfaces 44 and 45 and the bottom surface 38 of the groove 37 can be suppressed, thereby suppressing the occurrence of flare.

### 1-3 Modifications

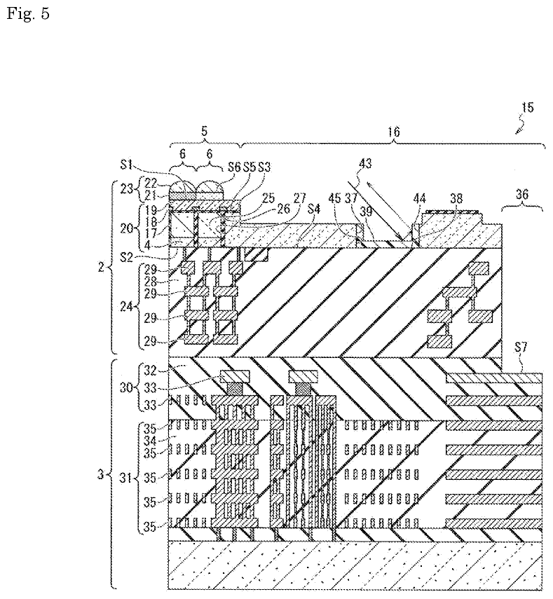

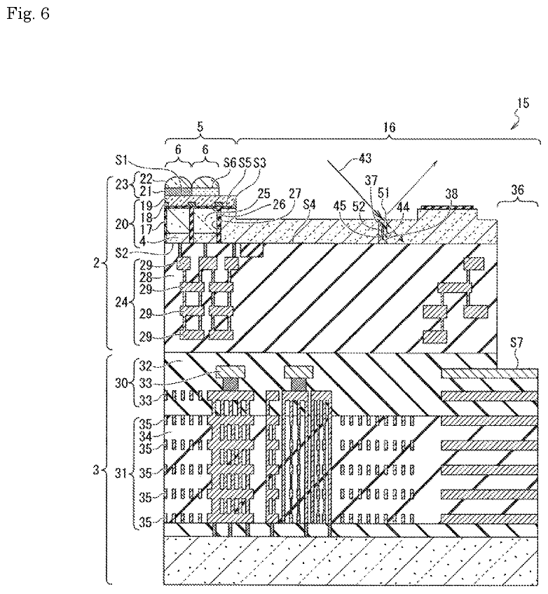

(1) In the example described in the first embodiment, the groove 37 is filled with the light absorber 39, but other configurations can be used. For example, as illustrated in FIG. 5, the light absorber 39 may cover at least one of the inner wall surface 44, which is directed toward the photoelectric conversion unit 25 in the groove 37, the opposite inner wall surface 45, and the bottom surface 38 of the groove 37. Since at least one of the inner wall surfaces 44 and 45 and the bottom surface 38 in this configuration, the amount of the light absorber 39 to be used can be reduced and lower cost can be achieved as compared with, for example, a configuration in which the groove 37 is filled with the light absorber 39. FIG. 5 illustrates a configuration in which the light absorber 39 seamlessly covers all of the inner wall surfaces 44 and 45 and the bottom surface 38 of the groove 37 and is not so thick as to fill a space in the groove 37.
(2) In the example described in the first embodiment, the light absorber 39 (light absorption material) is used as a material disposed in the groove 37, but other configurations can be used. For example, as illustrated in FIG. 6, the light absorber 39 may be replaced with a low-refractivity material 51 having a lower refractivity than a material (Si: a reflectivity of 3.8) forming the substrate 4.

FIG. 6 illustrates an example in which the low-refractivity material 51 is embedded to reach the opening of the groove 37. The low-refractivity material 51 may be, for example, silicon oxide (SiO₂: a refractivity of 1.5) or silicon nitride (SiN: a refractivity of 1.9). If two media having different refractivities are adjacent to each other, as a difference in refractivity decreases, the transmittance of light at the interface between the two media increases and the reflectivity of light at the interface decreases. Thus, the reflectivity of light at the interface between air (Air: a refractivity of 1.0) and the low-refractivity material 51 is lower than the reflectivity of light at the interface between air and the substrate 4 (Si: a reflectivity of 3.8). Hence, by embedding the low-refractivity material 51 to reach the opening of the groove 37, the reflection of the incident light 43 in the groove 37 can be suppressed and the return of the reflected incident light 43 to the pixel region 5 can be suppressed as compared with, for example, the case where the groove 37 is not filled with the low-refractivity material 51 and the inner wall surfaces 44 and 45 (substrate 4) are exposed in the groove 37, thereby suppressing the occurrence of flare.

Moreover, in the low-refractivity material 51, a cylindrical space (gap 52) is formed. The sides of the gap 52 near the inner wall surfaces 44 and 45, the bottom surface 38, and the opening end of the groove 37 are surrounded by the low-refractivity material 51, and the gap 52 extends along the groove 37. The width of the gap 52 can be, for example, about 20% of the width of the groove 37. Since the low-refractivity material 51 has the gap 52, a stress concentration is likely to occur in the low-refractivity material 51, so that the low-refractivity material 51 becomes prone to breakage. Thus, even if the substrate 4 peels off or cracks from the blade region 36 toward the pixel region 5, for example, during dicing, the gap 52 blocks the peeling or cracks, so that the extension of peeling or cracks into the pixel region 5 can be prevented. The ratio of the depth and the width of the groove 37 (depth/width: an aspect ratio) is preferably 3 or more, more preferably 5 or more. When the ratio of the depth to the width is smaller than 3, the formation of the gap 52 is difficult. For example, when the groove 37 has a depth of 3.5 μm, the width of the groove 37 is set at 1.1 μm or less.

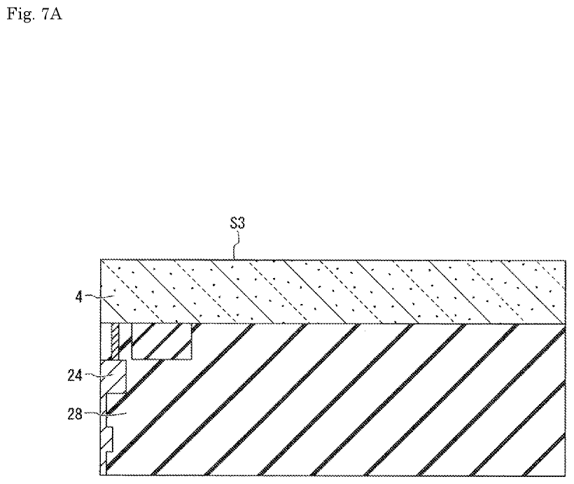

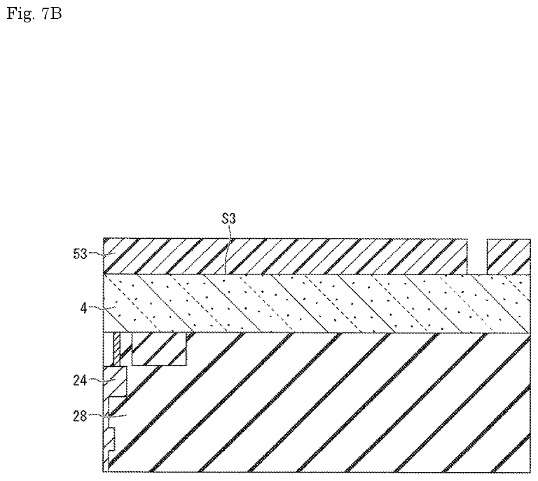

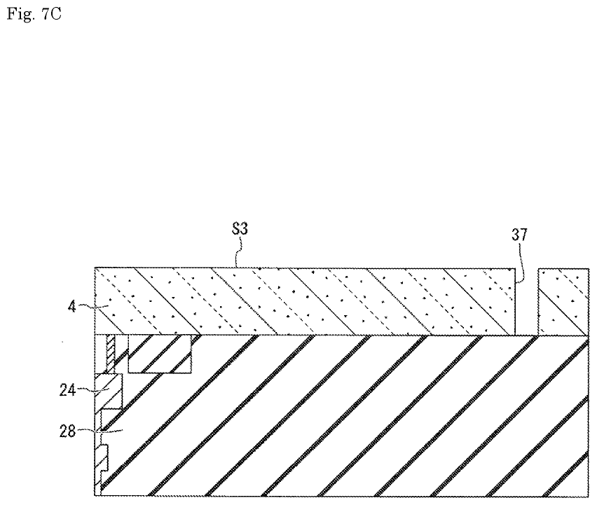

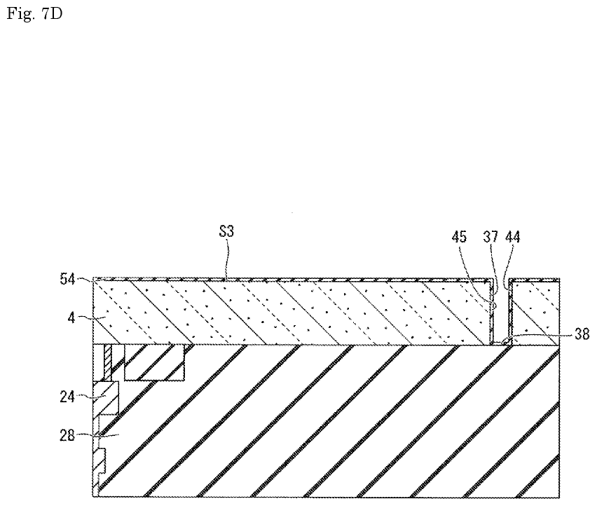

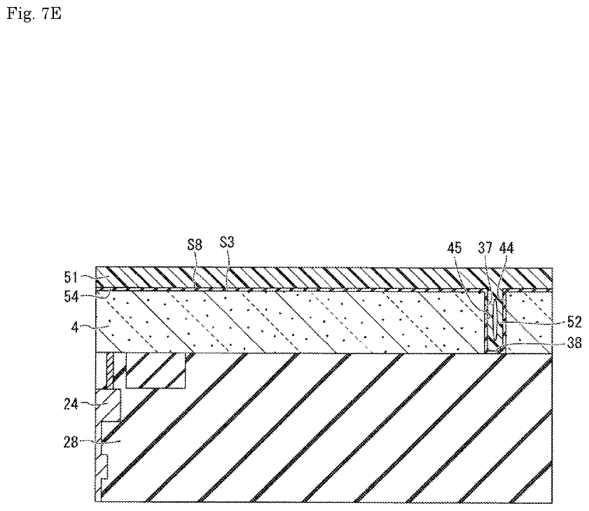

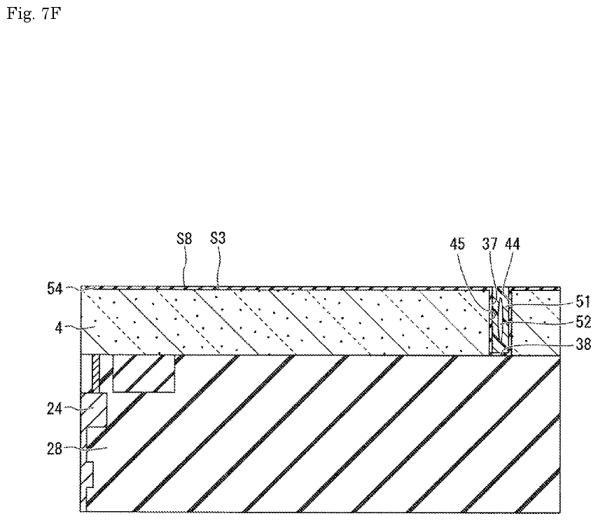

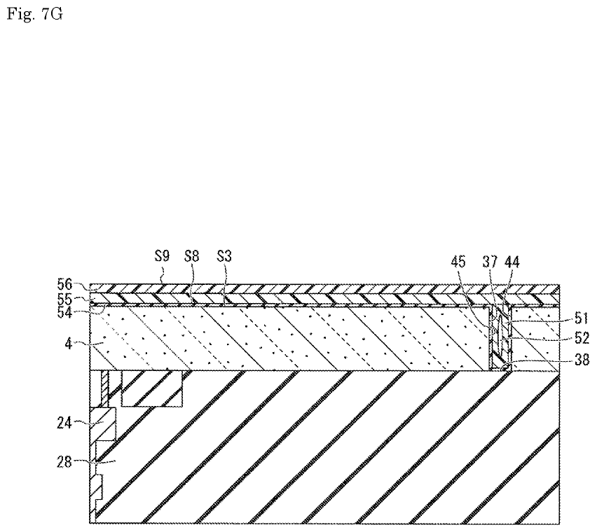

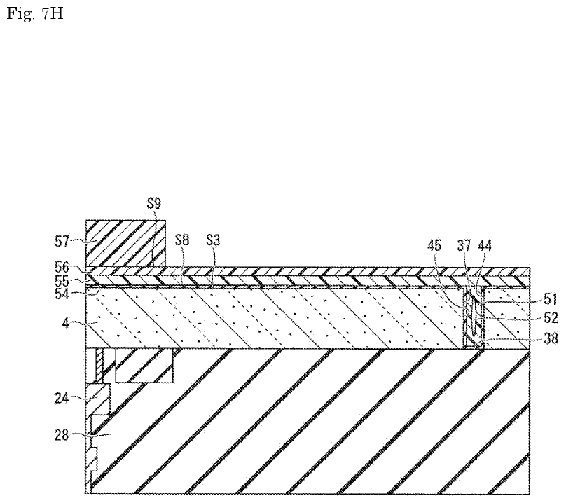

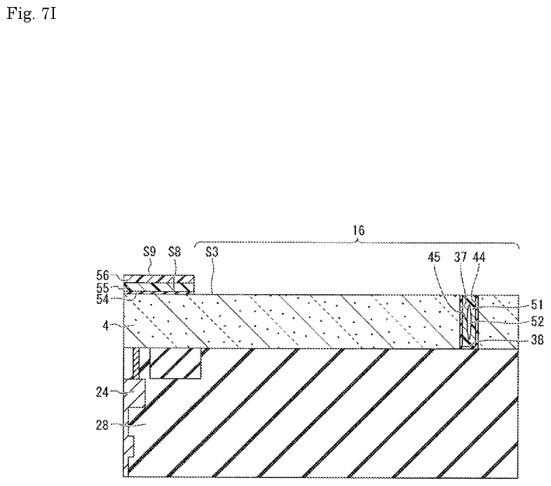

A method of manufacturing the chip 15 will be described below. FIGS. 7A, 7B, 7C, 7D, 7E, 7F, 7G, 7H, and 7I are diagrams illustrating the steps of forming the groove 37.

First, as illustrated in FIG. 7A, the substrate 4 is prepared according to the process of manufacturing a typical CMOS image sensor of the backside irradiation type after the completion of steps immediately before the step of forming the pixel separating portions 26. Thereafter, a resist film 53 is formed on the back side S3 of the substrate 4, and then a pattern is formed on the formed resist film 53 by photolithography as illustrated in FIG. 7B. In the formation of the pattern, openings are formed at positions aligned with the positions of the groove 37 and the trench portion 27 (see FIG. 6) on the resist film 53. The substrate 4 is then dry etched from the back side S3 of the substrate 4 while the resist film 53 having the openings is used as an etching mask. By dry etching, the groove 37 and the trench portion 27 having the same shapes as the openings of the etching mask (see FIG. 6) are formed on the substrate 4 as illustrated in FIG. 7C.

Subsequently, as illustrated in FIG. 7C, the etching mask (resist film 53) is removed from the back side S3 of the substrate 4, and then a fixed charge film 54 is formed using ALD (Atomic Layer Deposition) or CVD (Chemical Vapor Deposition) so as to seamlessly cover the inner wall surfaces 44 and 45 and the bottom surface 38 of the groove 37 and the back side S3 of the substrate 4 as illustrated in FIG. 7D. The fixed charge film 54 has a negative fixed charge generated by an oxygen dipole and has the function of strengthening the pinning of the photoelectric conversion units 25. The fixed charge film 54 can be made of an oxide or a nitride that contains at least one element selected from the group consisting of hafnium (HO, aluminum (Al), zirconium (Zr), thallium (Tl), and titanium (Ti). Alternatively, the fixed charge film 54 can be made of an oxide or a nitride that contains at least one element of lanthanum (La), cerium (Ce), neodymium (Nd), promethium (Pm), samarium (Sm), europium (Eu), gadolinium (Gd), terbium (Tb), dysprosium (Dy), holmium (Ho), thulium (Tm), ytterbium (Yb), lutetium (Lu), and yttrium (Y). Furthermore, the fixed charge film 54 can be made of a hafnium oxynitride or aluminum oxynitride. Moreover, silicon or nitrogen can be added to the fixed charge film 54 such that the amount of silicon or nitrogen does not degrade insulation. This can improve the heat resistance and the like. The thickness of the fixed charge film 54 is controlled in view of a wavelength and a refractivity. The fixed charge film 54 also acts as an antireflection coating for the substrate 4 having a high refractivity.

Subsequently, as illustrated in FIG. 7E, a back side S8 of the fixed charge film 54 is entirely covered by using HDP-CVD (High-Density Plasma Chemical Vapor Deposition), and the low-refractivity material 51 is deposited to fill the groove 37. The low-refractivity material 51 serving as the insulating film 17 fills the trench portion 27 (see FIG. 6). HDP-CVD is a method of deposition in which ions are drawn by applying power (bias power) to the substrate 4; meanwhile, sputtering is performed to obtain an excellent filling property. In the step of depositing the low-refractivity material 51, the condition of deposition is determined such that the opening end of the groove 37 is closed before the groove 37 is filled with the low-refractivity material 51. Specifically, the low-refractivity material 51 is first deposited with applied bias power to increase the amount of deposition on the inner wall surfaces 44 and 45 and the bottom surface 38 of the groove 37. The low-refractivity material 51 is then deposited without bias power to close the opening of the groove 37.

Subsequently, as illustrated in FIG. 7F, the low-refractivity material 51 is removed from the back side S8 of the fixed charge film 54 such that the low-refractivity material 51 is left only in the groove 37. By removing the low-refractivity material 51 from the back side S8 of the fixed charge film 54, the low-refractivity material 51 containing the gap 52 can be disposed in the groove 37. The inner space of the gap 52 is formed like a frame extended along the groove 37.

Subsequently, as illustrated in FIG. 7G, an STSR film 55 (e.g., an acrylic styrene resin film) and an LTO (Low Temperature Oxide) film 56 are formed in this order on the back side S8 of the fixed charge film 54. Thereafter, a resist film 57 is formed on a back side S9 of the LTO film 56, and then a pattern is formed on the formed resist film 57 by photolithography as illustrated in FIG. 7H. In the formation of the pattern, an opening is formed at the position of the scribe region 16 on the resist film 57. The substrate 4 is then dry etched from the back side S9 of the LTO film 56 while the resist film 57 having the opening is used as an etching mask. By dry etching, the scribe region 16 having the same cross-sectional shape as the opening of the etching mask is formed on the LTO film 56, the STSR film 55, and the substrate 4 as illustrated in FIG. 7I.

Thereafter, as illustrated in FIG. 7I, the etching mask (resist film 57) is removed from the back side S9 of the LTO film 56, and then the steps immediately before the step of forming the blade region 36 are completed according to the process of manufacturing a typical CMOS image sensor of the backside irradiation type. Subsequently, the blade region 36 surrounding the pixel region 5 is formed from the back side S3 of the substrate 4, and then the blade region 36 is diced (divided) with a blade, thereby forming the chips 15 (see FIG. 6).

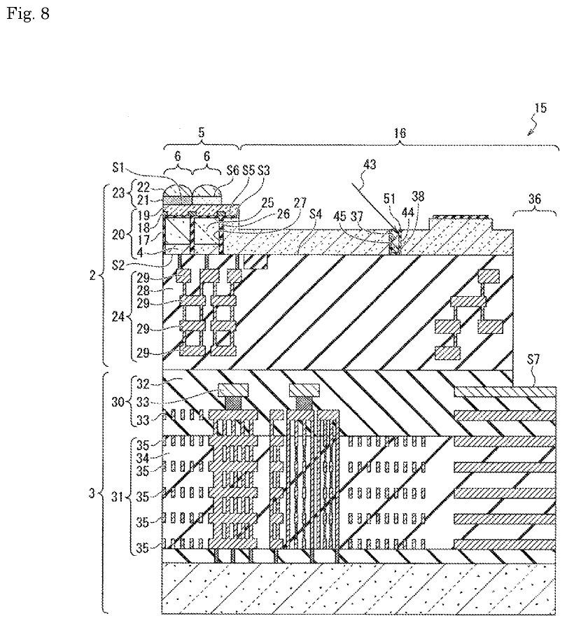

(3) Moreover, in the use of the low-refractivity material 51, the low-refractivity material 51 may seamlessly cover the inner surfaces (the inner wall surfaces 44 and 45 and the bottom surface 38) of the groove 37 and is not so thick as to fill a space in the groove 37 as illustrated in, for example, FIG. 8. By covering the inner surfaces of the groove 37 with the low-refractivity material 51, the reflection of the incident light 43 in the groove 37 can be suppressed and the return of the return of the reflected incident light 43 to the pixel region 5 can be suppressed as compared with, for example, the case where the inner surfaces of the groove 37 are not covered with the low-refractivity material 51 and the inner wall surfaces 44 and 45 (silicon making up the substrate 4 (Si: a reflectivity of 3.8)) are exposed in the groove 37, thereby suppressing the occurrence of flare. Since the low-refractivity material 51 is not so thick as to fill the space in the groove 37, even if the substrate 4 peels off or cracks from the blade region 36 toward the pixel region 5, for example, during dicing, the space in the groove 37 blocks the peeling or cracks, so that the extension of peeling or cracks into the pixel region 5 can be prevented.

If the low-refractivity material 51 is, for example, silicon oxide or silicon nitride, the low-refractivity material 51 preferably has a thickness of about 80 nm. Specifically, the thickness is preferably 75 nm to 85 nm and is more preferably 78 nm to 82 nm. As a result of a simulation of a reflectivity between air and a silicon oxide film or a reflectivity between air and a silicon nitride film, a reflectivity R at the interface between air and the low-refractivity material 51 was minimized when the silicon oxide film or the silicon nitride film was about 80 nm in thickness. The simulation was performed by using a simulation tool that uses expression R={(n₈−n²)/(nₛ+n²)}²) and the film type and the thickness of the low-refractivity material 51. In this expression, nₛ is the refractivity of air, and n is the refractivity of the low-refractivity material 51. For example, when the thickness is about 80 nm and the depth of the groove 37 is about 3.5 μm, the groove 37 has a width of about 1.8 μm to 8.8 μm.

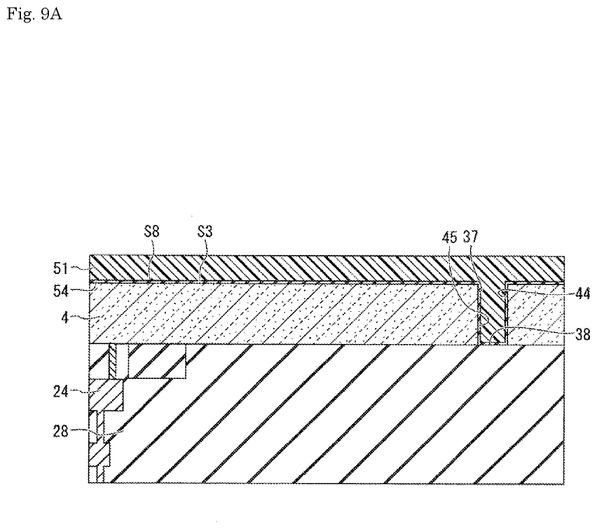

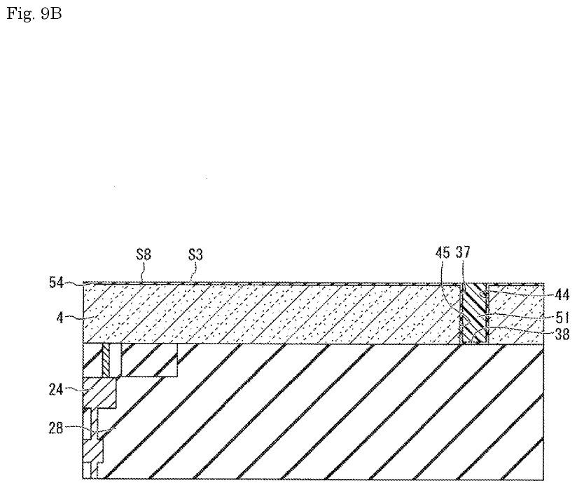

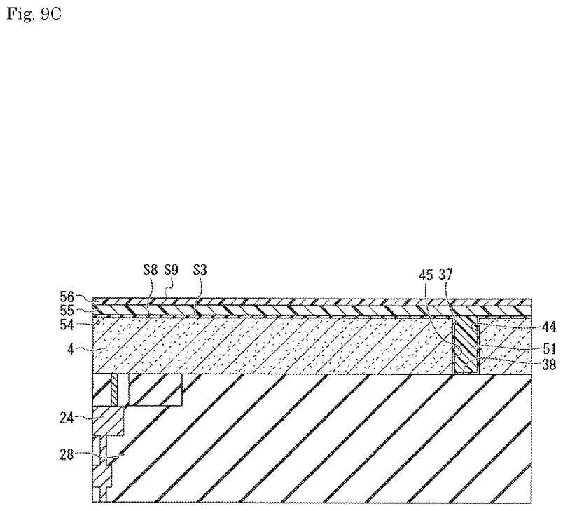

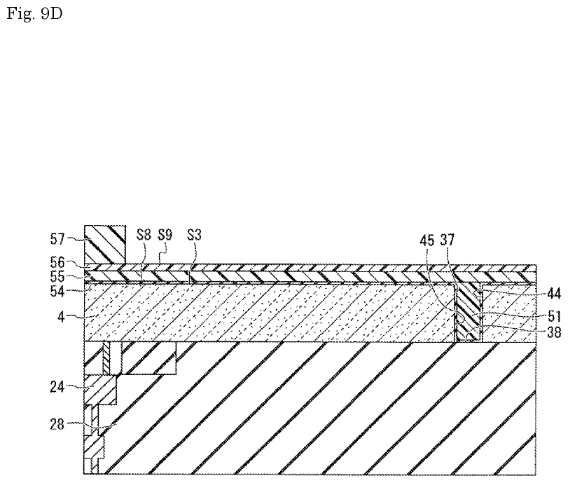

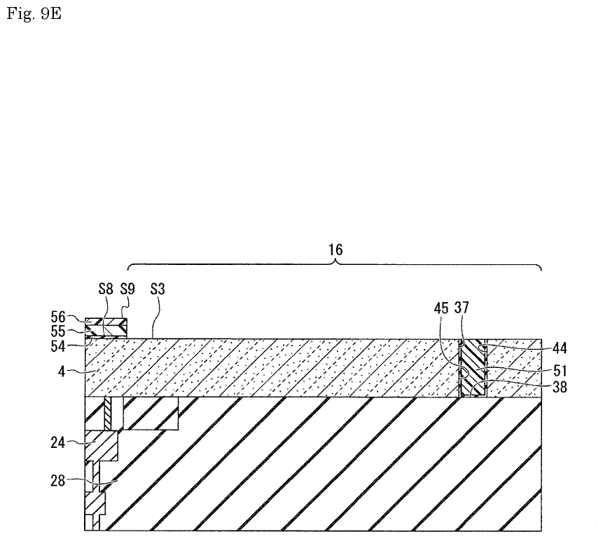

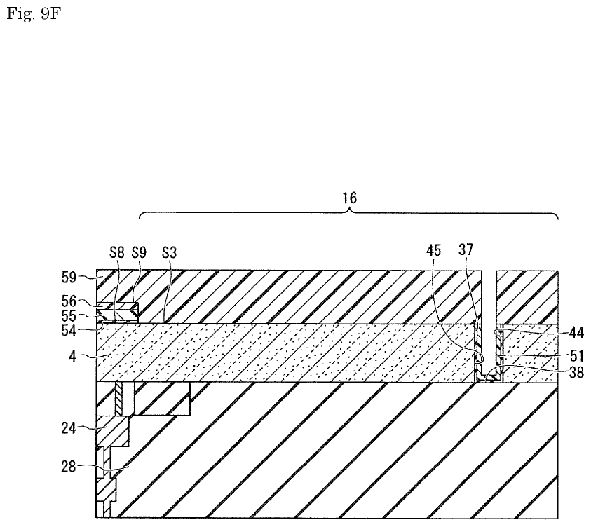

A method of manufacturing the chip 15 will be described below. FIGS. 9A, 9B, 9C, 9D, 9E, and 9F are diagrams illustrating the steps of forming the groove 37. First, as in the steps of FIGS. 7A to 7D, the fixed charge film 54 is formed so as to seamlessly cover the inner wall surfaces 44 and 45 and the bottom surface 38 of the groove 37 and the back side S3 of the substrate 4. Subsequently, as illustrated in FIG. 9A, the back side S8 of the fixed charge film 54 is entirely covered by using HDP-CVD, and the low-refractivity material 51 is deposited to fill the groove 37 (see FIG. 8). In the step of depositing the low-refractivity material 51, the condition of deposition is determined such that the groove 37 is filled with the low-refractivity material 51 before the opening end of the groove 37 is closed. Thus, the groove 37 is closed without leaving a gap in the low-refractivity material 51. As in the steps of FIGS. 7A to 7F, the low-refractivity material 51 serving as the insulating film 17 fills the trench portion 27 (see FIG. 8).

Subsequently, as illustrated in FIG. 9B, the low-refractivity material 51 is removed from the back side S8 of the fixed charge film 54 such that the low-refractivity material 51 is left only in the groove 37. Subsequently, as illustrated in FIG. 9C, the STSR film 55 and the LTO film 56 are formed in this order on the back side S8 of the fixed charge film 54. Thereafter, the resist film 57 is formed on the back side S9 of the LTO film 56, and then a pattern is formed on the formed resist film 57 by photolithography as illustrated in FIG. 9D. In the formation of the pattern, an opening is formed at the position of a recessed portion in the scribe region 16 on the resist film 57. The substrate 4 is then dry etched from the back side S9 of the LTO film 56 while the resist film 57 having the opening is used as an etching mask. By dry etching, the recessed portion in the scribe region 16 having the same cross-sectional shape as the opening of the etching mask is formed on the LTO film 56, the STSR film 55, and the substrate 4 as illustrated in FIG. 9E.

Subsequently, as illustrated in FIG. 9E, the etching mask (resist film 57) is removed from the back side S9 of the LTO film 56, a resist film 59 is formed on the back side S9 of the LTO film 56 and the back side S3 of the substrate 4 (including the low-refractivity material 51 in the groove 37), and then a pattern is formed on the formed resist film 59 by photolithography as illustrated in FIG. 9F. In the formation of the pattern, on the resist film 59, an opening is formed at a position aligned with the central portion of the low-refractivity material 51 in the thickness direction in the groove 37. The low-refractivity material 51 in the groove 37 is then dry etched from the back side S3 of the substrate 4 while the resist film 59 having the opening is used as an etching mask. By dry etching, the opening having the same cross-sectional shape as the opening of the etching mask is formed on the low-refractivity material 51 in the groove 37. By forming the opening on the low-refractivity material 51, the low-refractivity material 51 can be formed such that the low-refractivity material 51 seamlessly covers the inner surfaces of the groove 37 and is not so thick as to fill the space in the groove 37 (e.g., 80 nm in thickness).

Thereafter, the steps immediately before the step of forming the blade region 36 are completed according to the process of manufacturing a typical CMOS image sensor of the backside irradiation type. Subsequently, the blade region 36 surrounding the pixel region 5 is formed from the back side S3 of the substrate 4, and then the blade region 36 is diced (divided) with a blade, thereby forming the chips 15 (see FIG. 8).

### 2. Second Embodiment: Solid-State Imaging Device

### [2-1 Configurations of Main Part]

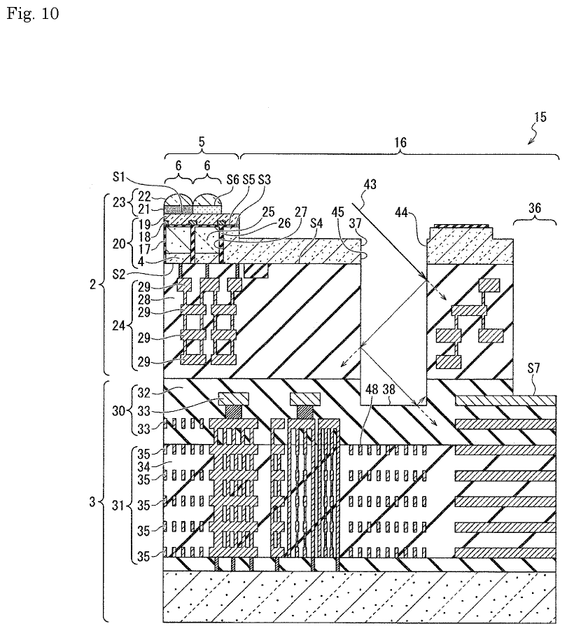

A solid-state imaging device according to a second embodiment of the present disclosure will be described below. The overall configuration of the solid-state imaging device according to the second embodiment is not illustrated because the configuration is similar to that of FIG. 1. FIG. 10 is a diagram illustrating a cross-sectional configuration of the main part of a solid-state imaging device 1 according to the second embodiment. In FIG. 10, parts corresponding to those in FIG. 3 are given the same reference signs, and redundant descriptions thereof will not be given.

In the solid-state imaging device 1 according to the second embodiment, the depth of a groove 37 is different from that of the first embodiment. In the second embodiment, as illustrated in FIG. 10, the groove 37 is so deep as to penetrate a substrate 4. Specifically, the groove 37 is so deep as to penetrate a sensor substrate 2, and a bottom surface 38 of the groove 37 is placed in a logic substrate 3. In FIG. 10, the bottom surface 38 of the groove 37 is placed in a first multilayer wiring layer 30 of the logic substrate 3.

Typically, the layers of a second multilayer wiring layer 31, that is, layers made of a Low-k material have small thicknesses, so that wirings 35 having a low density are likely to reduce the flatness. Thus, in order to obtain the flatness of the layers, a dummy pattern 48 of copper (Cu) dots is disposed in each layer of the second multilayer wiring layer 31. Thus, the dummy pattern 48 of copper (Cu) dots leads to difficulty in etching for forming the groove 37 in the second multilayer wiring layer 31. In contrast, the layers of the first multilayer wiring layer 30, that is, the layers made of silicon oxide with TEOS used as source gas are larger in thickness than the second multilayer wiring layer 31 and require only a few dummy patterns of copper (Cu) dots, enabling etching for forming the groove 37. Hence, in the second embodiment, the groove 37 penetrates the sensor substrate 2 (the substrate 4, a wiring layer 24) and the bottom surface 38 of the groove 37 is placed in the first multilayer wiring layer 30 (the layer on the second multilayer wiring layer 31). This configuration facilitates the formation of the groove 37.

Moreover, in the groove 37, a light absorber 39 is omitted and an empty space is formed instead.

As described above, in the solid-state imaging device 1 according to the second embodiment, the groove 37 between a blade region 36 and a pixel region 5 is so deep as to penetrate the sensor substrate 2. Thus, incident light 43 entering the groove 37 can be repeatedly reflected between inner wall surfaces 44 and 45 of the groove 37, thereby increasing the number of reflections of the incident light 43. In this case, an interlayer insulation film 28 (silicon oxide) of the wiring layer 24 has a reflectivity of about 1% or less. Thus, the incident light 43 reflected by the inner wall surfaces 44 and 45 in the wiring layer 24 is considerably attenuated by a single reflection and becomes sufficiently weak when returning to the light receiving surface of the sensor substrate 2.

Moreover, 99% of the incident light 43 entering the inner wall surfaces 44 and 45 scatters through a metallic pattern (wirings 29) in the wiring layer 24 and hardly returns to the light receiving surface of the sensor substrate 2. This can reduce the amount of the incident light 43 returning to the pixel region 5, thereby providing the solid-state imaging device 1 capable of suppressing the occurrence of flare.

### [2-2 Modifications]

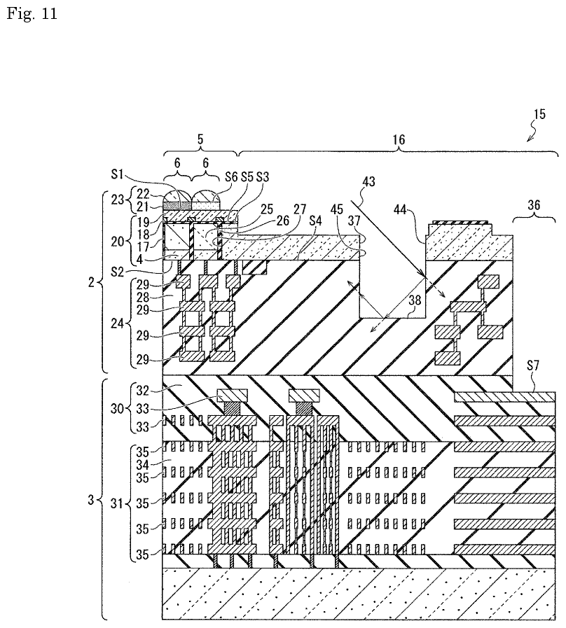

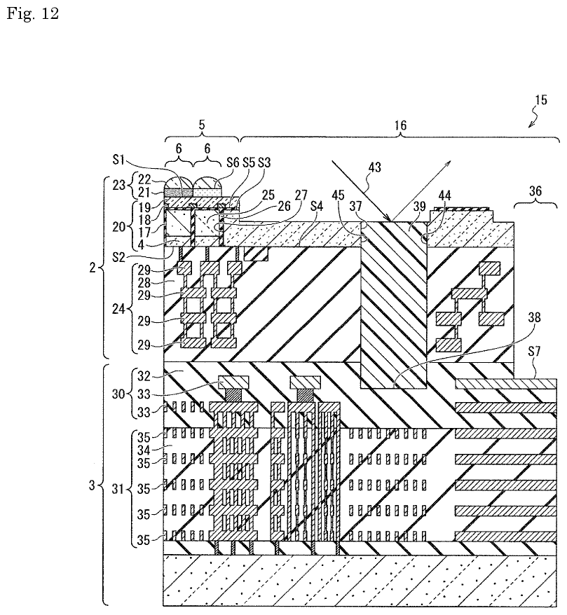

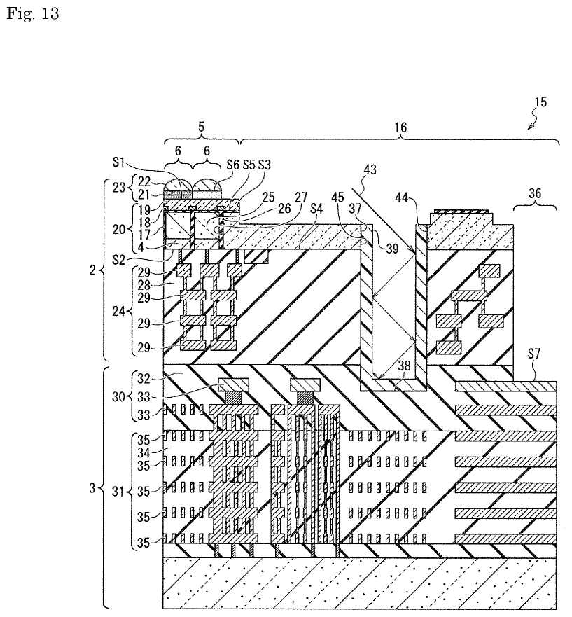

(1) In the example described in the second embodiment, the groove 37 is so deep as to penetrate the sensor substrate 2, but other configurations can be used. For example, as illustrated in FIG. 11, the groove 37 may be so deep as to penetrate the substrate 4 of the sensor substrate 2 but is not so deep as to penetrate the wiring layer 24 of the sensor substrate 2, and the bottom surface 38 of the groove 37 may be placed in the wiring layer 24.
(2) In the example described in the second embodiment, the groove 37 is empty. For example, as illustrated in FIGS. 12 and 13, the light absorber 39 may be disposed in the groove 37 as in the solid-state imaging device 1 according to the first embodiment. FIG. 12 illustrates a configuration in which the light absorber 39 is embedded to reach an opening in the groove 37 and fills the space in the groove 37. FIG. 13 illustrates a configuration example in which the light absorber 39 covers at least one of the inner wall surface 44, which is directed toward a photoelectric conversion unit 25 in the groove 37, the opposite inner wall surface 45, and the bottom surface 38 of the groove 37. As in the modification of the first embodiment, the light absorber 39 of FIGS. 12 and 13 may be replaced with the low-refractivity material 51 illustrated in FIGS. 6 and 8.

### 3. Third Embodiment: Solid-State Imaging Device

### [3-1 Configurations of Main Part]

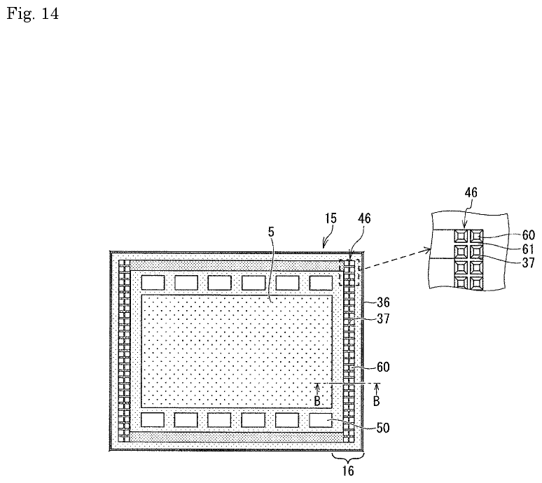

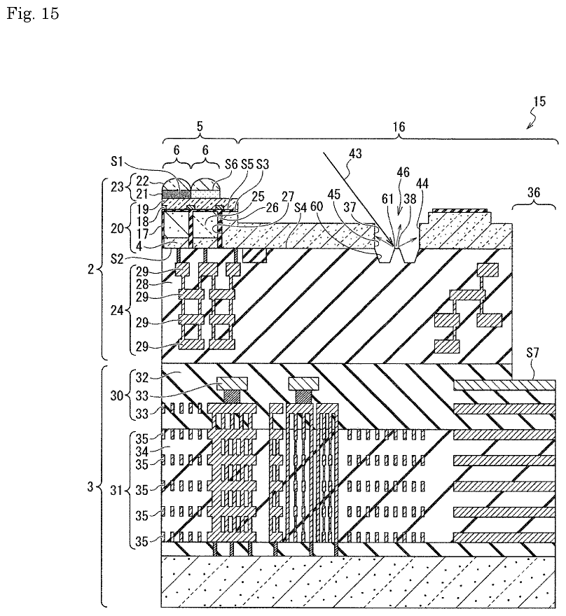

A solid-state imaging device according to a third embodiment of the present disclosure will be described below. The overall configuration of the solid-state imaging device according to the third embodiment is not illustrated because the configuration is similar to that of FIG. 1. FIG. 14 is a diagram illustrating a planar configuration of a pixel region 5 and a peripheral region thereof (scribe region 16) in a chip 15 where a solid-state imaging device 1 according to the third embodiment is formed. FIG. 15 is a diagram illustrating a cross-sectional configuration of the chip 15 along line B-B of FIG. 14. In FIGS. 14 and 15, parts corresponding to those in FIGS. 2A and 3 are given the same reference signs, and redundant descriptions thereof will not be given.

In the solid-state imaging device 1 according to the third embodiment, the shape of a bottom surface 38 of a groove 37 is different from that of the first embodiment. In the third embodiment, as illustrated in FIGS. 14 and 15, an uneven pattern 46 is formed on the bottom surface 38 of the groove 37. FIG. 14 illustrates the case where the uneven pattern 46 is formed only on the bottom surface 38 on some of the four sides of the groove 37 while I/O pads 50 are not present between the sides (the left side and the right side in FIG. 14) and the pixel region 5. The uneven pattern 46 can be, for example, a pattern having a plurality of convex portions, a pattern having a plurality of recessed portions, and a pattern having convex portions and recessed portions. In view of a reduction in manufacturing cost, the same pattern as an uneven pattern on the light receiving surface of the pixel region 5 is preferably used to flatten irregularities on a surface in the pixel region 5. In FIGS. 14 and 15, a pattern having a plurality of recessed portions 60 is used as the uneven pattern 46.

In the use of the pattern having the plurality of recessed portions 60, recessed portions shaped like inverted frustums may be used as the recessed portions 60. For example, the inner wall surfaces of the recessed portions are inclined such that the opening areas decrease in the depth direction. The recessed portions shaped like inverted frustums can be, for example, the recessed portions of inverted n-gonal pyramids (n is an integer of 3 or larger) or the recessed portions of inverted circular cones. In FIGS. 14 and 15, the recessed portions 60 shaped like inverted quadrangular pyramids are used. For example, when the depth of the groove 37 is about 3.5 μm and the width of the groove 37 is about 2.5 μm (numeric values determined from a point in a manufacturing tolerance by i-ray lithography), one side of the opening of the recessed portion 60 is set at about 1 μm, one side of the bottom of the recessed portion 60 is set at about 500 nm, and the depth of the recessed portion 60 is set at about 1.9 μm. A tilt angle α of the inner wall surface of the recessed portion 60 relative to the bottom surface of the recessed portion 60 is set at 70° to 80° in view of the scatter of incident light 43.

Moreover, as the layout pattern of the recessed portions 60, for example, a pattern having the recessed portions 60 regularly placed in a two-dimensional array can be used as illustrated in FIG. 14. In FIG. 14, the number of columns is two in the layout pattern of the recessed portions 60. Since recessed portions shaped like inverted frustums are used as the recessed portions 60 of the uneven pattern 46, the incident light 43 entering the groove 37 can be more strongly scattered and the return of the reflected incident light 43 to the pixel region 5 can be suppressed, thereby suppressing the occurrence of flare. Moreover, the groove 37 is not filled with a light absorber 39 and the like. Thus, even if the substrate 4 peels off or cracks, for example, during dicing, the peeling and the like can be prevented from extending into the pixel region 5. Furthermore, a flat region 61 having no recessed portions is formed between the adjacent recessed portions 60. The width of the flat region 61 (that is, an interval between the recessed portions 60) is set at, for example, about 500 nm.

Moreover, the bottom surface 38 of the groove 37 is formed by a surface S4 facing a substrate 4 of a wiring layer 24 as in the first embodiment. In other words, the bottom surface 38 of the groove 37 and the uneven pattern 46 of the bottom surface 38 are formed by an interlayer insulation film 28 (e.g., silicon oxide (SiO₂)) of the wiring layer 24. The deepest portion (the bottom of the recessed portion 60) of the uneven pattern 46 is located in the wiring layer 24.

### [3-2 Method of Manufacturing Chip]

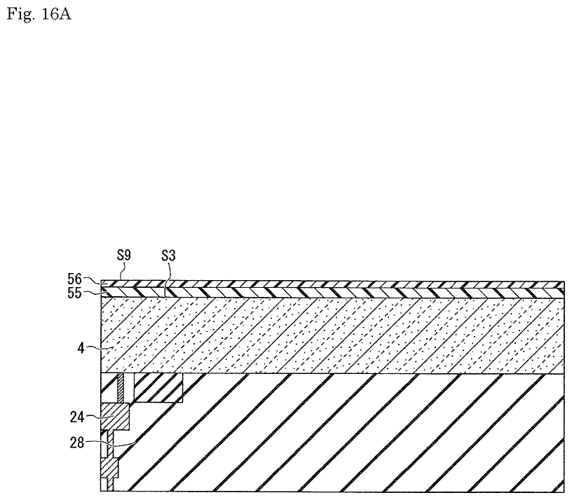

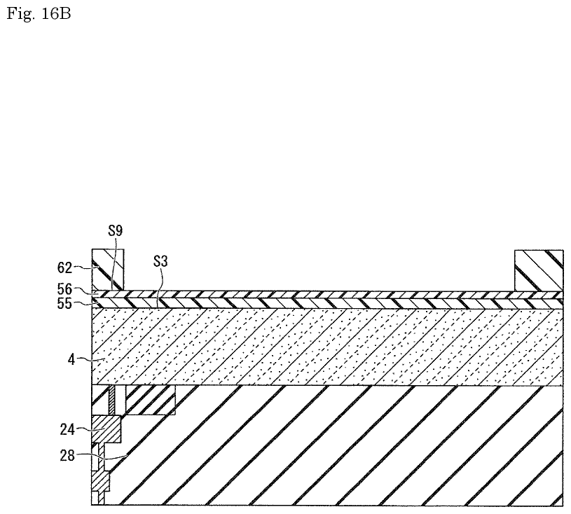

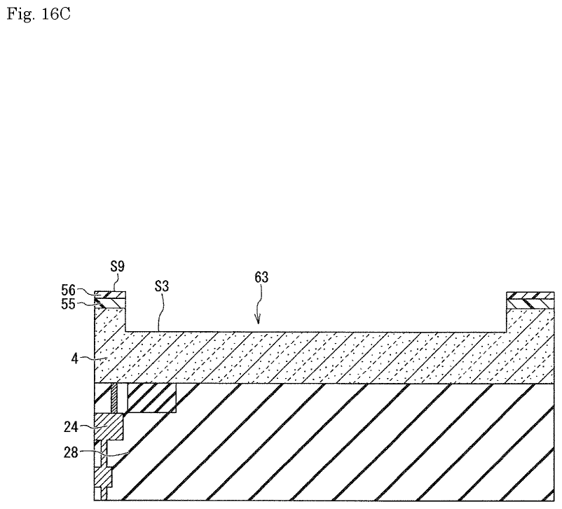

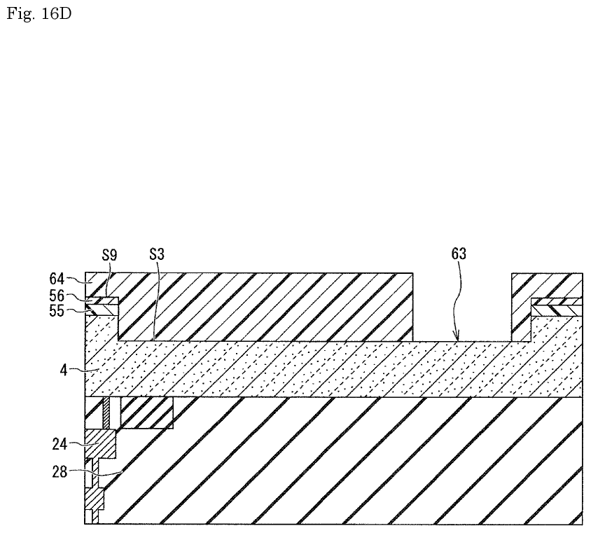

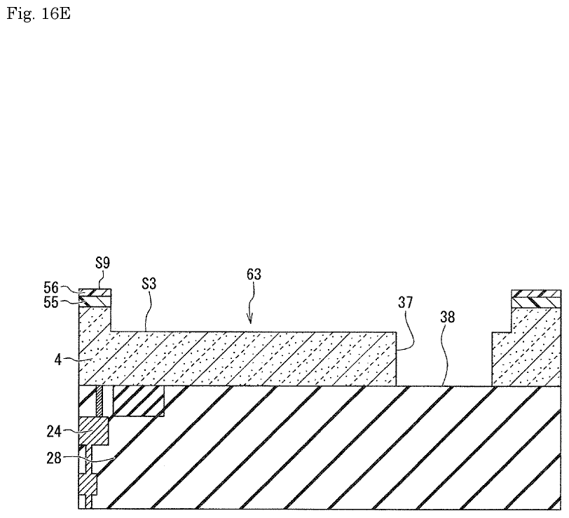

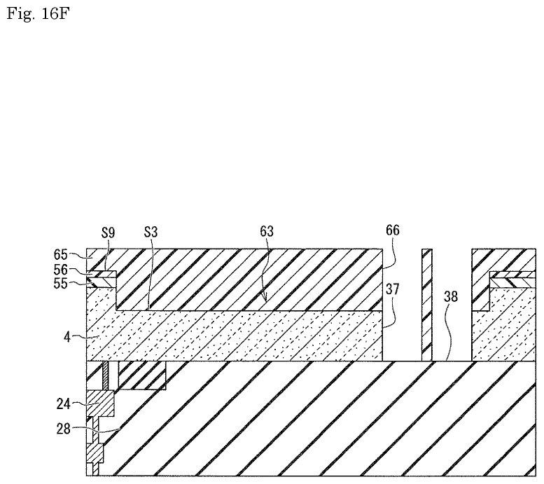

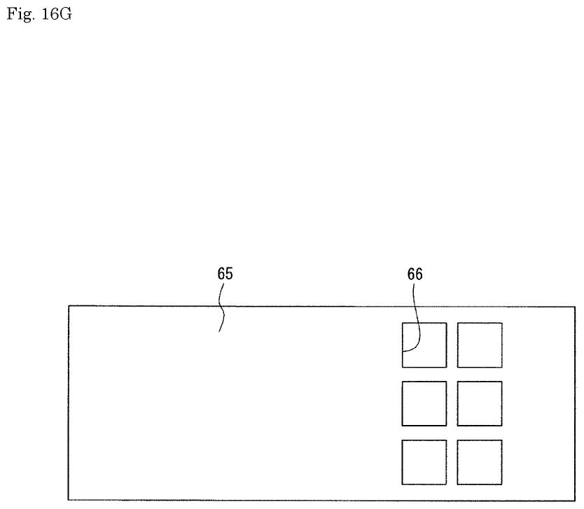

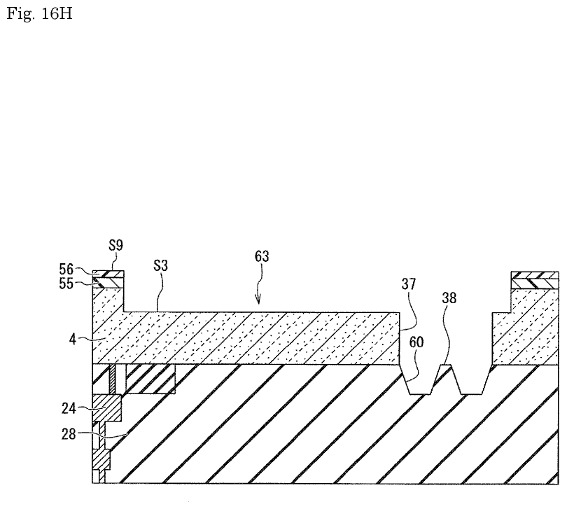

A method of manufacturing the chip 15 will be described below. FIGS. 16A, 16B, 16C, 16D, 16E, 16F, and 16H are diagrams illustrating the steps of forming the groove 37. FIG. 16G is a diagram illustrating a planar configuration of openings 66 formed on a resist film 65 of FIG. 16F.

First, as illustrated in FIG. 16A, the substrate 4 is prepared according to the process of manufacturing a typical CMOS image sensor of the backside irradiation type (solid-state imaging device 1), the substrate 4 having an STSR film 55 and an LTO film 56 that are formed in this order on a back side S3. Thereafter, a resist film 62 is formed on a back side S9 of the LTO film 56, and then a pattern is formed on the formed resist film 62 by photolithography as illustrated in FIG. 16B. In the formation of the pattern, an opening shaped like a frame is formed around the position of the pixel region 5 on the resist film 62 in plan view. The LTO film 56, the STSR film 55, and the substrate 4 are then dry etched from the back side S9 of the LTO film 56 while the resist film 62 having the opening is used as an etching mask. By dry etching, a recessed portion 63 having the same cross-sectional shape as the opening of the etching mask is formed on the LTO film 56, the STSR film 55, and the substrate 4 as illustrated in FIG. 16C.

Subsequently, as illustrated in FIG. 16C, the etching mask (resist film 62) is removed from the back side S9 of the LTO film 56. Thereafter, a resist film 64 is formed in the recessed portion 63 and on the back side S9 of the LTO film 56, and then a pattern is formed on the formed resist film 64 by photolithography as illustrated in FIG. 16D. In the formation of the pattern, an opening is formed at a position aligned with the position of the groove 37 on the resist film 64. The bottom of the recessed portion 63 is then dry etched from the back side S3 of the substrate 4 while the resist film 64 having the opening is used as an etching mask. By dry etching, the groove 37 having the same cross-sectional shape as the opening of the etching mask is formed on the substrate 4 as illustrated in FIG. 16E.

Subsequently, as illustrated in FIG. 16E, the etching mask (resist film 64) is removed from the inside of the recessed portion 63 and the back side S9 of the LTO film 56. Thereafter, the resist film 65 is formed in the recessed portion 63 (including the groove 37 in the recessed portion 63) and on the back side S9 of the LTO film 56, and then a pattern is formed on the formed resist film 65 by photolithography as illustrated in FIG. 16F. In the formation of the pattern, on the resist film 65, the openings 66 are formed at positions aligned with the positions of the recessed portions 60 at the bottom surface 38 of the groove 37 as illustrated in FIG. 16G. The bottom surface 38 of the groove 37 (the interlayer insulation film 28 of the wiring layer 24) is then subjected to crystal anisotropy etching while the resist film 65 having the openings 66 is used as an etching mask. By crystal anisotropy etching, the recessed portions 60 shaped like inverted quadrangular pyramids are formed on the interlayer insulation film 28 of the wiring layer 24.

Thereafter, as illustrated in FIG. 16H, the etching mask (resist film 65) is removed from the insides of the recessed portions 60 (including the groove 37 in the recessed portion 60) and the back side S9 of the LTO film 56, and then the steps immediately before the step of forming a blade region 36 are completed according to the process of manufacturing a typical CMOS image sensor of the backside irradiation type. Subsequently, the blade region 36 surrounding the pixel region 5 is formed from the back side S3 of the substrate 4, and then the blade region 36 is diced (divided) with a blade, thereby forming the chips 15 (see FIGS. 14 and 15).

As described above, in the solid-state imaging device 1 according to the third embodiment, the uneven pattern 46 is provided on the bottom surface 38 of the groove 37 between the blade region 36 and the pixel region 5. Thus, the bottom surface 38 of the groove 37 can be roughened, and the incident light 43 entering the groove 37 can be reflected in various directions through the uneven pattern 46, so that the incident light 43 can be scattered. Thus, the solid-state imaging device 1 can be provided such that the return of the reflected incident light 43 to the pixel region 5 can be prevented, and the entry of the reflected incident light 43 into the pixel region 5 can be prevented, so that the amount of the incident light 43 returning to the pixel region 5 can be reduced to suppress the occurrence of flare.

### [3-3 Modification]

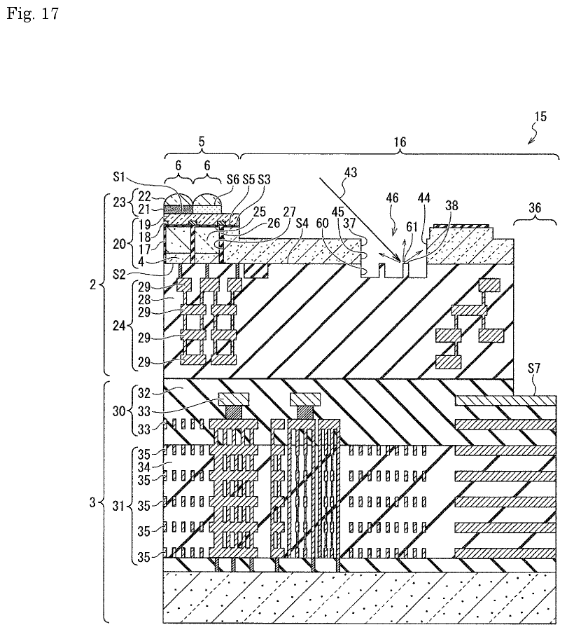

In the example described in the third embodiment, the recessed portions shaped like inverted frustums are used as the recessed portions 60 of the uneven pattern 46, but other configurations can be used. For example, as illustrated in FIG. 17, the recessed portions may have inner wall surfaces perpendicular to the bottom surfaces of the recessed portions 60.

### 4. Fourth Embodiment: Solid-State Imaging Device

### [4-1 Configuration of Main Part]

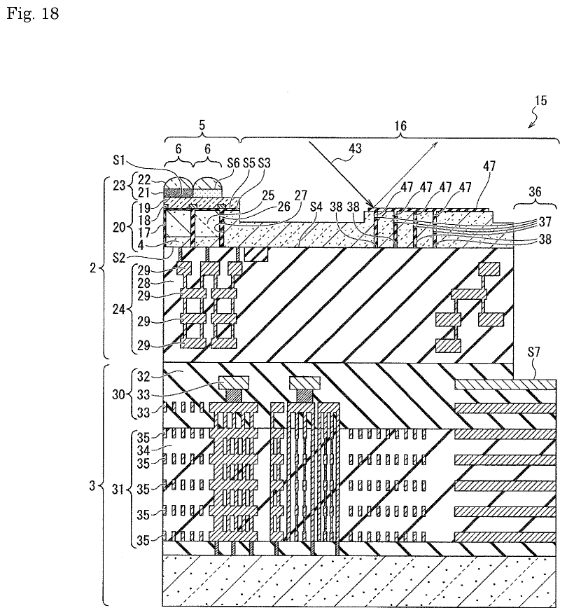

A solid-state imaging device according to a fourth embodiment of the present disclosure will be described below. The overall configuration of the solid-state imaging device according to the fourth embodiment is not illustrated because the configuration is similar to that of FIG. 1. FIG. 18 is a diagram illustrating a cross-sectional configuration of the main part of a solid-state imaging device 1 according to the fourth embodiment. In FIG. 18, parts corresponding to those in FIG. 3 are given the same reference signs, and redundant descriptions thereof will not be given.

In the solid-state imaging device 1 according to the fourth embodiment, the number of grooves 37 is different from that of the first embodiment. In the fourth embodiment, as illustrated in FIG. 18, the grooves 37 (four grooves in FIG. 18) are formed in parallel around a pixel region 5. In other words, in FIG. 18, the four grooves 37 surround the pixel region 5. An interval between the grooves 37 is equal to an interval between pixel separating portions 26 of the pixel region 5. Moreover, a bottom surface 38 of the groove 37 is formed by a surface S4 facing a substrate 4 of a wiring layer 24, like the bottom surface of a trench portion 27.

In other words, the groove 37 and the trench portion 27 have equal depths. Moreover, the grooves 37 are each filled with a light-reflective material 47 that reflects light. The light-reflective material 47 seamlessly covers the insides and openings of the grooves 37 and the substrate 4 around the openings of the grooves 37. Thus, the surface of the light-reflective material 47 covering the openings of the grooves 37 is flattened. As the light-reflective material 47, for example, the same insulating material as an insulating film 17 of a pixel region 5 can be used. For example, silicon oxide and silicon nitride can be used.

Moreover, the width of the groove 37 is equal to the width of the pixel separating portion 26 (the width of the trench portion 27).

As described above, in the solid-state imaging device 1 according to the fourth embodiment, the multiple grooves 37 are provided between a blade region 36 and the pixel region 5. Moreover, the light-reflective material 47 is provided to cover and flatten the openings of the grooves 37 and reflect light. Thus, for example, when incident light 43 enters the grooves 37, the incident light 43 can be reflected opposite to the pixel region 5 by the flattened light-reflective material 47. Thus, the return of the reflected incident light 43 to the pixel region 5 can be prevented, and the entry of the reflected incident light 43 into the pixel region 5 can be prevented. This can reduce the amount of the incident light 43 returning to the pixel region 5, thereby providing the solid-state imaging device 1 capable of suppressing the occurrence of flare.

Moreover, in the solid-state imaging device 1 according to the fourth embodiment, the grooves 37 and the pixel separating portions 26 are formed with equal intervals, equal depths, equal widths, and the same insulating material.

Thus, the grooves 37 and the pixel separating portions 26 can be formed at the same time, thereby eliminating the need for additional steps and achieving inexpensive measures against flare.

### 5. Fifth Embodiment: Electronic Device

An electronic device according to a fifth embodiment of the present disclosure will be described below. FIG. 19 is a schematic configuration diagram of an electronic device 100 according to the fifth embodiment of the present disclosure.

As illustrated in FIG. 19, the electronic device 100 according to the fifth embodiment includes a solid-state imaging device 101, an optical lens 102, a shutter device 103, a driving circuit 104, and a signal processing circuit 105. In the electronic device 100 according to the fifth embodiment, an embodiment in which the sensor substrate 2 according to the first embodiment is used for an electronic device (for example, a camera) is shown as the solid-state imaging device 101.

The optical lens 102 forms an image of image light (incident light 106) from a subject on an imaging surface of the solid-state imaging device 101. Thereby, signal charges are accumulated in the solid-state imaging device 101 for a certain period. The shutter device 103 controls a light irradiation period and a light shielding period for the solid-state imaging device 101. The driving circuit 104 supplies a driving signal for controlling a transfer operation of the solid-state imaging device 101 and a shutter operation of the shutter device 103. An operation of transferring a signal to the solid-state imaging device 101 is performed by the driving signal (timing signal) supplied from the driving circuit 104. The signal processing circuit 105 performs various kinds of signal processing on signals (pixel signals) output from the solid-state imaging device 101. A video signal having been subjected to signal processing is stored in a storage medium such as a memory or is output to a monitor.

With this configuration, the electronic device 100 of the fifth embodiment suppresses flare in the solid-state imaging device 101, thereby improving the image quality of the video signal.

Note that the electronic device 100 to which the solid-state imaging device 1 can be applied is not limited to a camera, and the solid-state imaging device 1 can also be applied to other electronic devices. For example, the solid-state imaging device 1 may be applied to an imaging device such as a camera module for a mobile device such as a mobile phone. In the fifth embodiment, the solid-state imaging device 1 according to the first embodiment is used as the solid-state imaging device 101, but other configurations may be adopted. For example, the solid-state imaging device 1 according to the second for fourth embodiments may be used, or the solid-state imaging device 1 according to the first to fourth modifications may be used.

The present technique can also take on the following configurations.

(1) A solid-state imaging device including:
a substrate on which a plurality of photoelectric conversion units are formed;
a groove that is formed between a pixel region having the plurality of photoelectric conversion units and a blade region surrounding the pixel region such that the groove is opened near a light-receiving surface of the substrate and surrounds the pixel region; and
a light absorber that is disposed in the groove and absorbs light.
(2) The solid-state imaging device according to (1),
wherein the light absorber is embedded to reach an opening in the groove.
(3) The solid-state imaging device according to (1),
wherein the light absorber covers at least one of an inner wall surface, which is directed toward the photoelectric conversion unit of the groove, an opposite inner wall surface, and a bottom surface of the groove.
(4) The solid-state imaging device according to any one of (1) to (3),
wherein the light absorber is a resin containing at least one of carbon black, titan black, and pigment black.
(5) A solid-state imaging device including:
a substrate on which a plurality of photoelectric conversion units are formed;
a groove that is formed between a pixel region having the plurality of photoelectric conversion units and a blade region surrounding the pixel region such that the groove is opened near a light-receiving surface of the substrate and surrounds the pixel region; and
a low-refractivity material that is disposed in the groove and has a lower refractivity than a material forming the substrate.
(6) The solid-state imaging device according to (5),
wherein the low-refractivity material is embedded to reach an opening in the groove, and
the low-refractivity material has a gap extending along the groove.
(7) The solid-state imaging device according to (5),
wherein the low-refractivity material seamlessly covers inner surfaces of the groove and is not so thick as to fill a space in the groove.
(8) The solid-state imaging device according to (7),
wherein the low-refractivity material is silicon oxide or silicon nitride, and the low-refractivity material has a thickness of 75 nm to 85 nm.
(9) A solid-state imaging device including:
a substrate on which a plurality of photoelectric conversion units are formed;
a wiring layer stacked on an opposite side from a light-receiving surface of the substrate; and
a groove that is formed between a pixel region having the plurality of photoelectric conversion units and a blade region surrounding the pixel region such that the groove is opened near the light-receiving surface of the substrate and surrounds the pixel region,
where the groove is so deep as to penetrate the substrate.
(10) The solid-state imaging device according to (9), further including:
a sensor substrate including the substrate and the wiring layer; and
a logic substrate that is stacked on the sensor substrate and processes an electrical signal from the photoelectric conversion unit,
wherein the groove is so deep as to penetrate the sensor substrate, and
the groove has a bottom surface placed in the logic substrate.
(11) The solid-state imaging device according to (10),
wherein the logic substrate includes a first multilayer wiring layer bonded to the sensor substrate and a second multilayer wiring layer stacked on an opposite side from a surface of the first multilayer wiring layer, the surface being bonded to the sensor substrate,
the first multilayer wiring layer includes an interlayer insulation film containing silicon oxide,
the second multilayer wiring layer includes an interlayer insulation film containing a Low-k material, and
the bottom surface of the groove is placed in the first multilayer wiring layer.
(12) A solid-state imaging device comprising:
a substrate on which a plurality of photoelectric conversion units are formed; and a groove that is formed between a pixel region having the plurality of photoelectric conversion units and a blade region surrounding the pixel region such that the groove is opened near a light-receiving surface of the substrate and surrounds the pixel region,
wherein the groove has an uneven pattern on a bottom surface of the groove.
(13) The solid-state imaging device according to (12),
wherein the uneven pattern is a pattern having a plurality of recessed portions, and
the recessed portions are recessed portions having inner wall surfaces inclined to reduce opening areas of the recessed portions in the depth direction.
(14) The solid-state imaging device according to (13),
wherein the recessed portions are recessed portions shaped like inverted quadrangular pyramids.
(15) The solid-state imaging device according to (13) or (14), further including a wiring layer stacked on the substrate,
wherein the uneven pattern has a deepest portion in the wiring layer.
(16) A solid-state imaging device including:
a substrate on which a plurality of photoelectric conversion units are formed; and
a plurality of grooves that are formed between a pixel region having the plurality of photoelectric conversion units and a blade region surrounding the pixel region such that the grooves are opened near a light-receiving surface of the substrate and surround the pixel region; and
a light-reflective material that covers and flattens the openings of the plurality of grooves and reflects light.
(17) The solid-state imaging device according to (16),
wherein the light-reflective material is silicon oxide or silicon nitride.
(18) An electronic device including:
a solid-state imaging device including a substrate on which a plurality of photoelectric conversion units are formed, a groove that is formed between a pixel region having the plurality of photoelectric conversion units and a blade region surrounding the pixel region such that the groove is opened near a light-receiving surface of the substrate and surrounds the pixel region, and a light absorber that is disposed in the groove and absorbs light;
an optical lens that forms image light from a subject into an image on an imaging surface of the solid-state imaging device; and
a signal processing circuit that performs signal processing on a signal output from the solid-state imaging device.
(19) An electronic device including:
a solid-state imaging device including a substrate on which a plurality of photoelectric conversion units are formed, a groove that is formed between a pixel region having the plurality of photoelectric conversion units and a blade region surrounding the pixel region such that the groove is opened near a light-receiving surface of the substrate and surrounds the pixel region, and a low-refractivity material that is disposed in the groove and has a lower refractivity than a material forming the substrate;
an optical lens that forms image light from a subject into an image on an imaging surface of the solid-state imaging device; and
a signal processing circuit that performs signal processing on a signal output from the solid-state imaging device.
(20) An electronic device including:
a solid-state imaging device including a substrate on which a plurality of photoelectric conversion units are formed, a wiring layer stacked on an opposite side from a light-receiving surface of the substrate, and a groove that is formed between a pixel region having the plurality of photoelectric conversion units and a blade region surrounding the pixel region such that the groove is opened near the light-receiving surface of the substrate and surrounds the pixel region, wherein the groove is so deep as to penetrate the substrate;
an optical lens that forms image light from a subject into an image on an imaging surface of the solid-state imaging device; and
a signal processing circuit that performs signal processing on a signal output from the solid-state imaging device.
(21) An electronic device including:
a solid-state imaging device including a substrate on which a plurality of photoelectric conversion units are formed, and a groove that is formed between a pixel region having the plurality of photoelectric conversion units and a blade region surrounding the pixel region such that the groove is opened near the light-receiving surface of the substrate and surrounds the pixel region, the groove having an uneven pattern on the bottom surface of the groove;
an optical lens that forms image light from a subject into an image on an imaging surface of the solid-state imaging device; and
a signal processing circuit that performs signal processing on a signal output from the solid-state imaging device.
(22) An electronic device including:
a solid-state imaging device including a substrate on which a plurality of photoelectric conversion units are formed, a plurality of grooves that are formed between a pixel region having the plurality of photoelectric conversion units and a blade region surrounding the pixel region such that the grooves are opened near the light-receiving surface of the substrate and surround the pixel region, and a light-reflective material that covers and flattens the openings of the plurality of grooves and reflects light;
an optical lens that forms image light from a subject into an image on an imaging surface of the solid-state imaging device; and
a signal processing circuit that performs signal processing on a signal output from the solid-state imaging device.

### REFERENCE SIGNS LIST

1 Solid-state imaging device
2 Sensor substrate
3 Logic substrate
4 Substrate
5 Pixel region
6 Pixel
7 Vertical driving circuit
8 Column signal processing circuit
9 Horizontal driving circuit
10 Output circuit
11 Control circuit
12 Pixel driving wiring
13 Vertical signal line
14 Horizontal signal line
15 Chip
16 Scribe region
17 Insulating film
18 Light shielding film
19 Flattened film
20 Light receiving layer
21 Color filter layer
22 On-chip lens
23 Light collecting layer
24 Wiring layer
25 Photoelectric conversion unit
26 Pixel separating portion
27 Trench portion
28 Interlayer insulation film
29 Wiring
30 First multilayer wiring layer
31 Second multilayer wiring layer
32 Interlayer insulation film
33 Wiring
34 Interlayer insulation film
35 Wiring
36 Blade region
37 Groove
38 Bottom surface
39 Light absorber
40 Camera module
41 IR cut filter
42a, 42b, 42c, 42d, 42e Imaging lens
43 Incident light
44, 45 Inner wall surface
46 Uneven pattern
47 Light-reflective material
48 Dummy pattern
49 Wafer
50 I/O pad
51 Low-refractivity material
52 Gap
53 Resist film
54 Fixed charge film
55 STSR film
56 LTO film
57 Resist film
59 Resist film
60 Recessed portion
61 Flat region
62 Resist film
63 Recessed portion
64 Resist film
65 Resist film
66 Opening
100 Electronic device
101 Solid-state imaging device
102 Optical lens
103 Shutter device
104 Driving circuit
105 Signal processing circuit
106 Incident light

1. A solid-state imaging device comprising: a substrate on which a plurality of photoelectric conversion units are formed; and
a groove that is formed between a pixel region having the plurality of photoelectric conversion units and a blade region surrounding the pixel region such that the groove is opened near a light-receiving surface of the substrate and surrounds the pixel region; and
a light absorber that is disposed in the groove and absorbs light.

2. The solid-state imaging device according to claim 1, wherein the light absorber is embedded to reach an opening in the groove.

3. The solid-state imaging device according to claim 1, wherein the light absorber covers at least one of an inner wall surface, which is directed toward the photoelectric conversion unit of the groove, an opposite inner wall surface, and a bottom surface of the groove.

4. The solid-state imaging device according to claim 1, wherein the light absorber is a resin containing at least one of carbon black, titan black, and pigment black.

5. A solid-state imaging device comprising: a substrate on which a plurality of photoelectric conversion units are formed; and
a groove that is formed between a pixel region having the plurality of photoelectric conversion units and a blade region surrounding the pixel region such that the groove is opened near a light-receiving surface of the substrate and surrounds the pixel region; and
a low-refractivity material that is disposed in the groove and has a lower refractivity than a material forming the substrate.

6. The solid-state imaging device according to claim 5, wherein the low-refractivity material is embedded to reach an opening in the groove, and
the low-refractivity material has a gap extending along the groove.

7. The solid-state imaging device according to claim 5, wherein the low-refractivity material seamlessly covers inner surfaces of the groove and is not so thick as to fill a space in the groove.

8. The solid-state imaging device according to claim 7, wherein the low-refractivity material is silicon oxide or silicon nitride, and
the low-refractivity material has a thickness of 75 nm to 85 nm.

9. A solid-state imaging device comprising: a substrate on which a plurality of photoelectric conversion units are formed; and
a wiring layer stacked on an opposite side from a light-receiving surface of the substrate; and
a groove that is formed between a pixel region having the plurality of photoelectric conversion units and a blade region surrounding the pixel region such that the groove is opened near the light-receiving surface of the substrate and surrounds the pixel region,
where the groove is so deep as to penetrate the substrate.

10. The solid-state imaging device according to claim 9, further comprising a sensor substrate including the substrate and the wiring layer; and
a logic substrate that is stacked on the sensor substrate and processes an electrical signal from the photoelectric conversion unit,
wherein the groove is so deep as to penetrate the sensor substrate, and
the groove has a bottom surface placed in the logic substrate.

11. The solid-state imaging device according to claim 10, wherein the logic substrate includes a first multilayer wiring layer bonded to the sensor substrate and a second multilayer wiring layer stacked on an opposite side from a surface of the first multilayer wiring layer, the surface being bonded to the sensor substrate,
the first multilayer wiring layer includes an interlayer insulation film containing silicon oxide,
the second multilayer wiring layer includes an interlayer insulation film containing a Low-k material, and
the bottom surface of the groove is placed in the first multilayer wiring layer.

12. A solid-state imaging device comprising: a substrate on which a plurality of photoelectric conversion units are formed; and
a groove that is formed between a pixel region having the plurality of photoelectric conversion units and a blade region surrounding the pixel region such that the groove is opened near a light-receiving surface of the substrate and surrounds the pixel region,
wherein the groove has an uneven pattern on a bottom surface of the groove.

13. The solid-state imaging device according to claim 12, wherein the uneven pattern is a pattern having a plurality of recessed portions, and
the recessed portions are recessed portions having inner wall surfaces inclined to reduce opening areas of the recessed portions in a depth direction.

14. The solid-state imaging device according to claim 13, wherein the recessed portions are recessed portions shaped like inverted quadrangular pyramids.

15. The solid-state imaging device according to claim 13, further comprising a wiring layer stacked on the substrate,
wherein the uneven pattern has a deepest portion in the wiring layer.

16. A solid-state imaging device comprising: a substrate on which a plurality of photoelectric conversion units are formed; and
a plurality of grooves that are formed between a pixel region having the plurality of photoelectric conversion units and a blade region surrounding the pixel region such that the grooves are opened near a light-receiving surface of the substrate and surround the pixel region; and
a light-reflective material that covers and flattens the openings of the plurality of grooves and reflects light.

17. The solid-state imaging device according to claim 16, wherein the light-reflective material is silicon oxide or silicon nitride.

18. An electronic device comprising: a solid-state imaging device including a substrate on which a plurality of photoelectric conversion units are formed, a groove that is formed between a pixel region having the plurality of photoelectric conversion units and a blade region surrounding the pixel region such that the groove is opened near a light-receiving surface of the substrate and surrounds the pixel region, and a light absorber that is disposed in the groove and absorbs light;
an optical lens that forms image light from a subject into an image on an imaging surface of the solid-state imaging device; and
a signal processing circuit that performs signal processing on a signal output from the solid-state imaging device.

19. An electronic device comprising: a solid-state imaging device including a substrate on which a plurality of photoelectric conversion units are formed, a groove that is formed between a pixel region having the plurality of photoelectric conversion units and a blade region surrounding the pixel region such that the groove is opened near a light-receiving surface of the substrate and surrounds the pixel region, and a low-refractivity material that is disposed in the groove and has a lower refractivity than a material forming the substrate;
an optical lens that forms image light from a subject into an image on an imaging surface of the solid-state imaging device; and
a signal processing circuit that performs signal processing on a signal output from the solid-state imaging device.

20. An electronic device comprising: a solid-state imaging device including a substrate on which a plurality of photoelectric conversion units are formed, a wiring layer stacked on an opposite side from a light-receiving surface of the substrate, and a groove that is formed between a pixel region having the plurality of photoelectric conversion units and a blade region surrounding the pixel region such that the groove is opened near the light-receiving surface of the substrate and surrounds the pixel region, wherein the groove is so deep as to penetrate the substrate;
an optical lens that forms image light from a subject into an image on an imaging surface of the solid-state imaging device; and
a signal processing circuit that performs signal processing on a signal output from the solid-state imaging device.
